(19) United States
(12) Patent Application Publication
(10) Pub. No.: US 2002/0163086 A1
(43) Pub. Date: Nov. 7, 2002

(54) Semiconductor device and manufacturing method thereof

(76) Inventor: Yoshihiko Toyoda, Hyogo (JP)

Correspondence Address: LEYDIG VOIT & MAYER, LTD, 700 THIRTEENTH ST. NW, SUITE 300, WASHINGTON, DC, 20005-3960, US

(21) Appl. No.: 09/892,603

(22) Filed: Jun. 28, 2001

(30) Foreign Application Priority Data
Jan. 17, 2001 (JP) 2001-008724

(51) Int. Cl. B32B 3/30; B32B 1/00; H01L 23/48; H01L 29/40; D06N 7/04

(52) U.S. Cl. 257/773; 428/141; 428/156

(57) ABSTRACT

A plurality of grooves having different widths are formed on a surface of an insulating film. Interconnection constituted by a barrier metal and a Cu film is formed in a manner so as to be embedded in the respective grooves. Unevenness formed by, for example, a plurality of grooves are formed on a bottom portion of each of wide grooves having wide widths among the grooves. With this arrangement, it is possible to provide a semiconductor device and a manufacturing method thereof, which can reduce a difference in the deposition rate between the wide grooves and narrow grooves.

### BACKGROUND OF THE INVENTION

1. Field of the Invention

The present invention relates to a semiconductor device and a manufacturing method thereof, and more specifically to a semiconductor device having a multi-layer interconnection structure of an integrated circuit, and a manufacturing method thereof.

2. Description of the Background Art

FIG. 38 and FIGS. 39 to 41 show a structure of a conventional semiconductor device and a manufacturing method thereof, which are described on page 107 in “Monthly Semiconductor World”, December Issue, 1997. Referring to FIG. 38, a plurality of grooves 102a, 102b having different widths are formed in an insulating film 101 on a semiconductor substrate. A barrier metal 104 is formed along an inner surface of each of the grooves 102a, 102b, and a Cu (copper) film 105 is formed so as to be embedded in each of the grooves 102a, 102b. A interconnection layer is constituted by these barrier metal 104 and Cu film 105.

Next, an explanation will be given of a manufacturing method for the conventional semiconductor device shown in FIG. 38.

First, referring to FIG. 39, a resist pattern 111a is formed on the surface of the insulating film 101 by a photolithographic technique. The insulating film 101 is subjected to reactive ion etching by using this resist pattern 111a as a mask so that a plurality of the grooves 102a, 102b having different widths are formed in the insulating film 101. Thereafter, the resist pattern 111a is removed by ashing and a chemical treatment.

Referring to FIG. 40, a TaN (tantalum nitride) film is formed on the insulating film 101 on which grooves 102a, 102b are formed as the barrier metal 104, and a Cu film is further formed thereon as a seed layer 105a of a plated film.

Referring to FIG. 41, the Cu film 105 is thickly deposited on the entire surface by electrolytic plating in a plating liquid of a copper sulfate bath, so as to be embedded in the respective grooves 102a, 102b. At this time, the depositing rate becomes faster in narrow sections such as narrow grooves and holes 102b than in wide grooves 102a and flat face portions due to the effects of additives added in the plating liquid, with the result that the embedding is preferentially carried out in these portions, and thus, it is possible to obtain a superior embedding property. Moreover, the Cu film 105 formed in the portions except the grooves 102a, 102b is removed by a chemical mechanical polishing method (CMP method), thereby providing a semiconductor device shown in FIG. 38.

As described above, in the conventional manufacturing method of the semiconductor device, at the time when the Cu film 105 is plated, the depositing rate is slower in the wide groove 102a than in the narrow groove 102b. Therefore, in order to form a wide wire, the electrolytic plating process has to be continued until the wide groove 102a has been filled. For this reason, the plated film of the narrow groove 102b becomes much thicker than the plated film of the wide groove 102a. As a result of such a difference in film thickness, a step difference on the surface of the plated Cu film 105 became greater than the initial step difference at the time when the grooves 102a, 102b were formed.

This state is described on page 135 in Appendix (1) U.S. Session Program and Abstract of “Proceedings of Advanced Metallization Conference 1999: Asian Session”.

In order to remove all the thick Cu film 105 on the narrow groove 102b by the CMP method, the thin Cu film 105 on the wide groove 102a needs to be excessively abraded. As a result, the upper surface of wires 104, 105 formed inside the wide groove 102a is concaved. Consequently, there is a great increase in the resistivity of the wire inside the wide groove 102a, or there are great deviations in the resistivity.

Another problem is that such a concave-shaped dent causes a interconnection layer formed thereon to have remaining metal on its concave portion, resulting in generation of unwanted short-circuiting in the wire.

### SUMMARY OF THE INVENTION

An object of the present invention is to provide a semiconductor device and a manufacturing method thereof, which can reduce a difference in the depositing rate between a wide groove and a narrow groove.

A semiconductor device according to the present invention indicates an insulating layer having a surface in which a plurality of grooves having different widths are formed, and a conductive layer formed by filling the inside of each of the plurality of grooves with at least plating, wherein unevenness are formed on a bottom portion of some grooves among the plurality of grooves.

In accordance with the semiconductor device of the present invention, since an additive for suppressing the deposition of plating is hardly allowed to enter the unevenness formed on the bottom of the groove, the thickness of a film deposited at that time of plating becomes larger. For this reason, the unevenness are formed on the bottom portion of the groove having a wide width so that the depositing rate in a groove having a wide width is able to be made virtually equal to that in a groove having a narrow width. Therefore, since the step difference on the surface of the plated conductive layer is able to be made smaller so that, when the plated conductive layer is abraded by the CMP method, the upper surface of the wire having a wide width becomes unlikely to have a concave-shape dent.

In the above-mentioned semiconductor device, preferably, the unevenness are formed on a bottom portion of a groove that has a ratio of the depth to the width of not more than 0.7.

Thus, it becomes possible to fill the groove with a thinner plating film.

In the above-mentioned semiconductor device, more preferably, the unevenness are formed on a bottom portion of a groove that has a ratio of the depth to the width of not more than 0.35.

Thus, it becomes possible to fill the groove with a thinner plating film.

In the above-mentioned semiconductor device, preferably, the concave portion of the unevenness has a groove shape, and the concave portion has a ratio of the depth to the width of greater than 0.35.

With this arrangement, it is possible to effectively improve the depositing rate by plating.

In the above-mentioned semiconductor device, more preferably, the concave portion of the unevenness has a groove shape, and the concave portion has a ratio of the depth to the width of greater than 0.7

With this arrangement, it is possible to effectively improve the depositing rate by plating.

In the above-mentioned semiconductor device, more preferably, the concave portion of the unevenness has a hole shape, and the concave portion has a ratio of the depth to the aperture diameter of greater than 0.35.

With this arrangement, it is possible to effectively improve the depositing rate by plating.

In the above-mentioned semiconductor device, more preferably, the concave portion of the unevenness has a hole shape, and the concave portion has a ratio of the depth to the aperture diameter of greater than 0.7.

With this arrangement, it is possible to effectively improve the depositing rate by plating.

In the above-mentioned semiconductor device, more preferably, the concave portion of the unevenness has slanting side faces with the two side faces crossing each other in its cross-section.

With this arrangement, it is possible to effectively improve the depositing rate by plating, and also to make the depth of the concave portion of the unevenness shallower.

In the above-mentioned semiconductor device, preferably, the side face of the concave portion is slanted with an angle greater than 20 degrees against the upper surface of the insulating layer.

With this arrangement, it is possible to effectively improve the depositing rate by plating.

In the above-mentioned semiconductor device, the pitch of the concave portions of the unevenness is set to be not more than 4 times the width or the aperture diameter of the concave portion.

With this arrangement, it is possible to place the unevenness on the bottom portion of the groove more densely, thereby improving the plating rate more effectively by the unevenness.

The manufacturing method of a semiconductor device in accordance with the present invention is provided with the following steps.

First, a plurality of grooves having different widths are formed on a surface of an insulating layer and unevenness are formed on a bottom surface of each of some grooves among the plurality of grooves. Then, a metal film is deposited on the insulating layer by plating so as to be embedded in the grooves and the unevenness. Moreover, the metal film is continued to be removed by chemical mechanical polishing until at least the upper surface of the insulating layer is exposed so that the metal film is allowed to remain in the grooves and unevenness and forms a interconnection layer.

In accordance with the manufacturing method of a semiconductor device of the present invention, since an additive for suppressing the deposition of plating is hardly allowed to enter the unevenness formed on the bottom of the groove, the thickness of a film deposited at the time of plating becomes larger. For this reason, the unevenness are formed on the bottom portion of the groove having a wide width so that the depositing rate in a groove having a wide width is able to be made virtually equal to that in a groove having a narrow width. Therefore, since the step difference on the surface of the plated conductive layer is able to be made smaller so that, when the plated conductive layer is abraded by the CMP method, the upper surface of the wire having a wide width becomes unlikely to have a concave-shape dent.

The above-mentioned manufacturing method of the semiconductor device is more preferably provided with: a step of forming a lower interconnection layer as a lower layer beneath the insulating layer, and a step of forming a connection hole for connecting the lower interconnection layer and the interconnection layer in the insulating layer, and in this arrangement, prior to the formation of the grooves, the connection hole and the unevenness are simultaneously formed.

This arrangement makes it possible to simplify the manufacturing process.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross-sectional view that shows a construction of a semiconductor device in accordance with a first embodiment of the present invention;

FIG. 2 is a schematic perspective view that shows the construction of the semiconductor device in accordance with the first embodiment of the present invention;

FIG. 3 is a schematic perspective view that shows the construction of a semiconductor device in accordance with a second of the present invention;

FIG. 4 is a schematic cross-sectional view that shows a construction of a semiconductor device in accordance with a sixth embodiment of the present invention;

FIG. 5 is a schematic perspective view that shows the construction of the semiconductor device in accordance with the sixth embodiment of the present invention;

FIG. 6 is a schematic perspective view that shows the construction of the semiconductor device in accordance with a seventh embodiment of the present invention;

FIG. 7 is a schematic cross-sectional view that shows a construction of a semiconductor device in accordance with tenth embodiment of the present invention;

FIG. 8 is a schematic perspective view that shows the construction of the semiconductor device in accordance with the tenth embodiment of the present invention;

FIG. 9 is a schematic perspective view that shows another construction of the semiconductor device in accordance with the tenth embodiment of the present invention;

FIG. 10 is a schematic cross-sectional view that shows a construction of a semiconductor device in accordance with an eleventh embodiment of the present invention;

FIG. 11 is a schematic perspective view that shows the construction of the semiconductor device in accordance with the eleventh embodiment of the present invention;

FIG. 12 is a schematic perspective view that shows another construction of the semiconductor device in accordance with the eleventh embodiment of the present invention;

FIGS. 13 through 16 are schematic cross-sectional views that show a sequence of processes in a manufacturing method of a semiconductor device in accordance with a twelfth embodiment of the present invention;

FIGS. 17 through 21 are schematic cross-sectional views that show a sequence of processes in a manufacturing method of a semiconductor device in accordance with a thirteenth embodiment of the present invention;

FIGS. 22 through 26 are schematic cross-sectional views that show a sequence of processes in a manufacturing method of a semiconductor device in accordance with a fourteenth embodiment of the present invention;

FIGS. 27 through 31 are schematic cross-sectional views that show a sequence of processes in a manufacturing method of a semiconductor device in accordance with a fifteenth embodiment of the present invention;

FIGS. 32 through 37 are schematic cross-sectional views that show a sequence of processes in a manufacturing method of a semiconductor device in accordance with a sixteenth embodiment of the present invention;

FIG. 38 is a cross-sectional view that schematically shows a construction of a conventional semiconductor device; and

FIGS. 39 through 41 are schematic cross-sectional views that show a sequence of processes in a manufacturing method of the conventional semiconductor device.

### DESCRIPTION OF THE PREFERRED EMBODIMENTS

Referring to Figures, the following description will discuss preferred embodiments of the present invention.

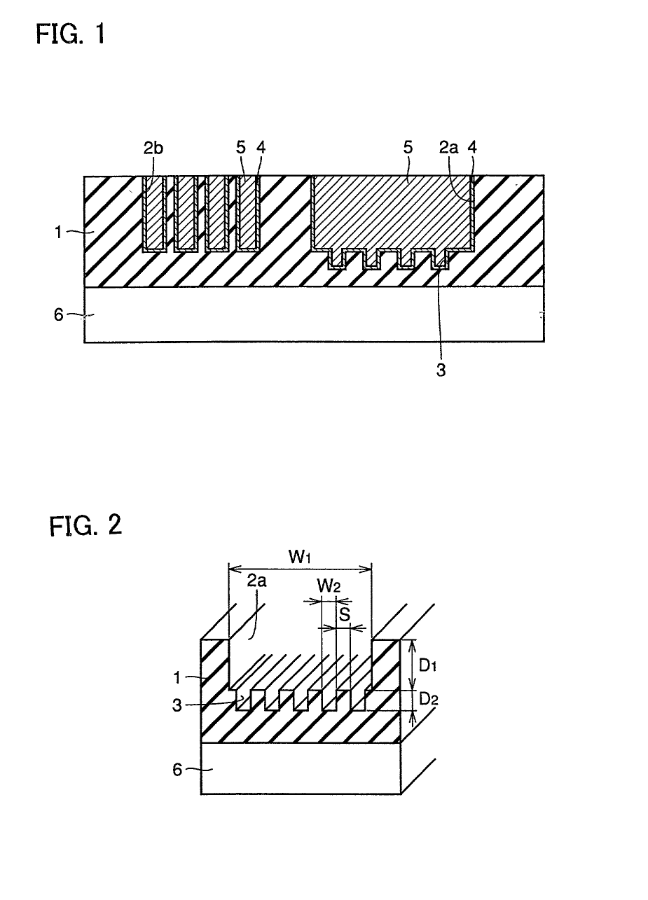

Referring to FIGS. 1 and 2, an insulating film 1 is formed on a semiconductor substrate or on an insulating film 6 forming a lower layer. A plurality of interconnection grooves 2a, 2b having mutually different widths are formed in the surface of the insulating film 1. In particular, unevenness 3 are formed on the bottom surface of the interconnection groove 2a having a wide width.

A barrier metal 4 made of, for example, TaN is formed along the inner surface of each of these interconnection grooves 2a, 2b, and a Cu film 5 is formed so as to be embedded in each of the interconnection grooves 2a, 2b. These barrier metal 4 and Cu film 5 constitute a interconnection layer, and the upper surfaces of the interconnection layers 4, 5 and the upper surface of the insulating film 1 virtually constitute the same plane.

The widths W1 of the respective interconnection grooves are set to, for example, 0.5, 5, 10 and 20 μm, and the depth D1 is set to, for example, 0.7 μm. A plurality of grooves serving as the unevenness 3 are formed on the bottom surface of each interconnection groove 2a having the width W1 of not less than 5 μm, along the length direction of the interconnection 5. The width W2 of the grooves serving as the unevenness is set to, for example, 0.4 μm, the space S is 0.6 μm, and the depth D2 is 0.5 μm.

Next, an explanation will be given of a manufacturing method of the present embodiment.

Referring to FIGS. 1 and 2, the insulating film 1 is formed on a semiconductor substrate or on an insulating film 6 formed as a lower layer. A resist pattern having a interconnection pattern formed therein is formed on the insulating film 1 by a photolithographic technique. The insulating film 1 is subjected to reactive ion etching by using this resist pattern as a mask so that the interconnection grooves 2a, 2b having a depth of, for example, 0.7 μm are formed in the insulating film 1. Thereafter, the resist pattern is removed by ashing.

As the groove-shaped concave and convex pattern, for example, a resist pattern with a groove pattern having a width of 0.4 μm is formed on the insulating film 1 by a photolithographic technique. The insulating film 1 is subjected to reactive ion etching by using this resist pattern as a mask so that groove-shaped unevenness 3 are formed only on the bottom portion of each interconnection groove 2a having a width of not less than 5 μm, with a depth of, for example, 0.5 μm. Thereafter, the resist pattern is removed by ashing.

For example, a TaN film is formed on the insulating film 1 as the barrier metal 4 by sputtering, with a thickness of 20 nm, and, for example, a Cu film is formed thereon as a seed layer for a plating film by sputtering, with a thickness of 150 nm.

An electrolytic plating process is carried out in a plating solution of a copper sulfate bath so that the Cu film 5 is formed until it has been embedded in the interconnection grooves 2a, 2b. The current for the electrolytic plating is set to, for example, 5A. Thereafter, the Cu film 5 and the barrier metal 4 are abraded and removed by the CMP method until at least the upper surface of the insulating film 1 has been exposed so that these are allowed to remain in the interconnection grooves 2a, 2b as a interconnection layer.

The inventors, etc., of the present invention carried out an examination on the surface step difference of the plating Cu film in comparison with cases with and without the formation of the groove-shaped unevenness 3 on the bottom surface of each interconnection groove 2a.

In the semiconductor device formed in the above-mentioned method, Table 1 shows the results of measurements carried out on the film thickness of the plating Cu film formed on the portions of the interconnection grooves and flat portions without the grooves. Here, the film thickness represents a value including the thickness of the Cu film serving as the seed layer.

TABLE 1
Effects of formation of groove-shaped unevenness on
the bottom of a interconnection groove

Cu film thickness (μm)

| Interconnection width | Without unevenness | With unevenness |
|---|---|---|
| (μm) | 800 nm plating | 400 nm plating |
| 0.5 | 2 | 1.1 |
| 5 | 0.7 | 0.7 |
| 10 | 0.7 | 0.7 |
| 20 | 0.7 | 0.7 |
| Flat portion | 0.7 | 0.35 |
| (from groove bottom) | (1.4) | (1.05) |

The amount of plating required for filling the interconnection groove was 400 nm in the case of the presence of the unevenness (grooves) on the bottom of the interconnection, and was 800 nm in the case of the absence of the unevenness (grooves) on the bottom of the interconnection. Here, the amount of plating refers to a thickness of the Cu film formed when plating is applied onto the flat substrate.

In the case of the absence of the unevenness (grooves) on the bottom of the interconnection groove, the highest portion of the surface of the Cu film was a interconnection portion having a width of 0.5 μm while the lowest portion was each of interconnection portions having widths of 5, 10 and 20 μm, and the step difference was 1.3 μm. In contrast, in the case of the presence of the unevenness (grooves) on the bottom of the interconnection groove, the highest portion of the surface of the Cu film was a interconnection portion having a width of 0.5 μm while the lowest portion was each of interconnection portions having widths of 5, 10 and 20 μm, and the step difference was 0.4 μm.

As described above, by forming the unevenness (grooves) on the bottom of the interconnection groove, the surface step difference was greatly reduced from 1.3 μm to 0.4 μm at the time when the interconnection grooves had been filled with the plating Cu film.

The reason for the reduction in the amount of plating required for filling the interconnection grooves was that the plating rate was increased by forming the groove-shaped unevenness on the bottom of the interconnection groove. The reason for the increase in the plating rate results from the effects of additives applied to the plating solution. In narrow grooves, the amount of the additives for suppressing the deposition of plating is small, while in wide grooves and flat portions, the additives for accelerating the deposition of plating are placed virtually in a uniform manner. For this reason, in the wide grooves and flat portions, the deposition of plating is suppressed, while in the narrow grooves, the deposition of plating is accelerated.

In the present embodiment, the explanation has been given of a case in which the groove-shaped unevenness 3 are formed in the length direction of the interconnection; however, these sections may be formed in the width direction of the interconnection and even in this case, the same effects are obtained.

(Second Embodiment)

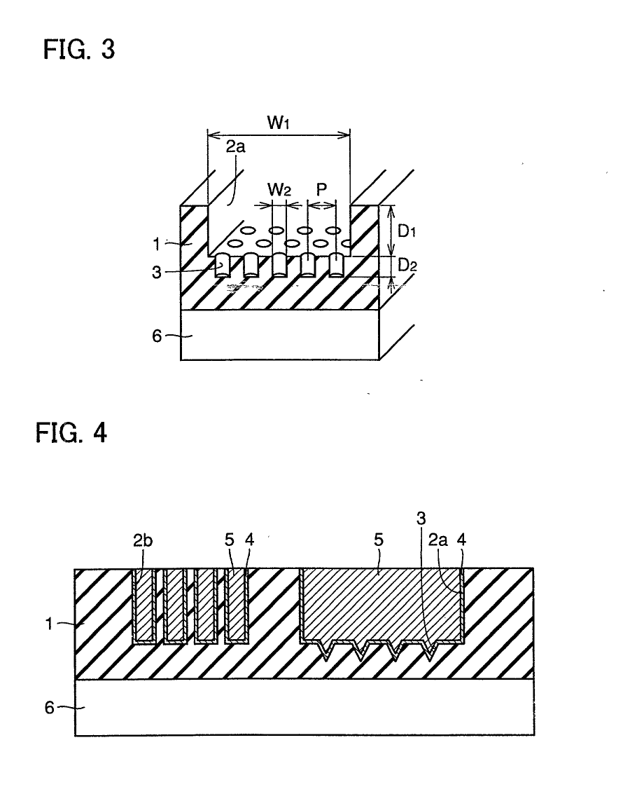

Referring to FIGS. 1 and 3, in the structures of the present embodiment, the shapes of the unevenness 3 are different from those of the first embodiment shown in FIG. 2. In the present embodiment, the unevenness 3 are provided as a plurality of holes formed in the bottom surface of the interconnection groove 2a. The holes constituting the unevenness 3 have a diameter W2 of, for example, 0.4 μm, and also have a pitch P of, for example, 1 μm and a depth D2 of, for example, 0.5 μm.

Here, the other structures except for the above-mentioned structure are virtually the same as those of the first embodiment; therefore, the same members are indicated by the same reference numbers, and the description thereof is omitted.

The manufacturing method in the present embodiment is also virtually the same as the manufacturing method of the first embodiment; therefore, the description thereof is omitted. In the fist embodiment, the groove-shaped unevenness 3 are formed by patterning; in contrast, in the present embodiment, unevenness 3 constituted by a plurality of holes are formed by patterning in this process.

The inventors, etc., of the present invention also carried out an examination on the surface step difference of the plating Cu film in the same manner as the first embodiment.

The widths W1 of the respective interconnection grooves were set to, for example, 0.5, 5, 10 and 20 μm, and the depth D1 was set to 0.7 μm. A plurality of holes serving as the unevenness, which have a diameter W2 of 0.4 μm, a pitch P of 1 μm and a depth D2 of 0.5 μm, were formed on the bottom surface of each interconnection groove 2a having the width W1 of not less than 5 μm. On this was formed a TaN film as the barrier metal by sputtering, with a thickness of 20 nm, and was further formed a Cu film as a seed layer for a plating film by sputtering, with a thickness of 150 nm. Next, an electrolytic plating process was carried out in a plating solution of a copper sulfate bath so that a Cu film was formed until it had been embedded in the interconnection grooves. The current for the electrolytic plating was set to 5A. For comparative purposes, the same structure without the unevenness (holes) on the bottom of the interconnection groove was formed in the same manner.

Against the substrate formed as described above, Table 2 shows the film thickness of the Cu film formed on each of the portions of the interconnection grooves and flat portions without the grooves. Here, the film thickness represents a value including the thickness of the Cu film serving as the seed layer.

TABLE 2
Effects of formation of hole-shaped unevenness on the
bottom of a interconnection groove

Cu film thickness (μm)

| Interconnection width | Without unevenness | With unevenness |
|---|---|---|
| (μm) | 800 nm plating | 400 nm plating |
| 0.5 | 2 | 1.05 |
| 5 | 0.7 | 0.8 |
| 10 | 0.7 | 0.8 |
| 20 | 0.7 | 0.8 |
| Flat portion | 0.7 | 0.3 |
| (from groove bottom) | (1.4) | (1.0) |

The amount of plating required for filling the interconnection groove was 400 nm in the case of the presence of the unevenness (holes) on the bottom of the interconnection, and was 800 nm in the case of the absence of the unevenness (holes) on the bottom of the interconnection. In the case of the absence of the unevenness (holes) on the bottom of the interconnection groove, the highest portion of the surface of the Cu film was a interconnection portion having a width of 0.5 μm while the lowest portion was each of interconnection portions having widths of 5, 10 and 20 μm, and the step difference was 1.3 μm. In contrast, in the case of the presence of the unevenness (holes) on the bottom of the interconnection groove, the highest portion of the surface of the Cu film was a interconnection portion having a width of 0.5 μm while the lowest portion was each of interconnection portions having widths of 5, 10 and 20 μm, and the step difference was 0.25 μm.

As described above, by forming the unevenness (holes) on the bottom of the interconnection groove, the surface step difference was greatly reduced from 1.3 μm to 0.25 μm at the time when the interconnection grooves had been filled with the plating Cu film.

The reason for the reduction in the amount of plating required for filling the interconnection grooves was that the plating rate was increased by forming the hole-shaped unevenness on the bottom of the interconnection groove. The mechanism of improving the plating rate is based upon the same principle as described in the first embodiment. Moreover, in comparison with the groove-shaped unevenness, the hole-shaped unevenness exert greater effects for improving the plating rate, thereby making it possible to further reduce the surface step difference.

(Third Embodiment)

The inventors, etc. of the present invention carried out an examination on the relationship between the plating Cu film thickness and the interconnection width.

Interconnection grooves having widths in the range of 0.34 to 20 μm were formed, and Cu films were formed on the interconnection grooves by plating; and the results are listed on Table 3.

TABLE 3
Relationship between Cu plating film thickness and interconnection width

| Interconnection width | Cu film thickness (μm) | |
|---|---|---|
| (μm) | Plating current 5A | Plating current 8A |
| 0.34 | 1.3 | 1.2 |
| 0.4 | 1.3 | 1.2 |
| 0.5 | 1.25 | 1.2 |
| 0.7 | 1.1 | 1 |
| 1 | 1.05 | 0.4 |
| 1.4 | 1 | 0.4 |
| 2 | 0.4 | 0.4 |
| 5 | 0.4 | 0.4 |
| 10 | 0.4 | 0.4 |
| 20 | 0.4 | 0.4 |
| Flat portion | 0.4 | 0.4 |

In this case, the depth of the interconnection grooves was 0.7 μm, and on this formed a TaN film as the barrier metal by sputtering, with a thickness of 20 nm, and was further formed a Cu film as a seed layer for a plating film by sputtering, with a thickness of 150 nm. Next, an electrolytic plating process was carried out so that a Cu film having a thickness of 400 nm was formed. The current at this time was set to 5A or 8A. When the plating current was 5A, it was not possible to fill the interconnection grooves in the case of a interconnection width of not less than 2 μm, that is, an aspect ratio (depth/width) of not more than 0.35. Moveover, when the plating current was 8A, it was not possible to fill the interconnection grooves in the case of a interconnection width of not less than 1 μm, that is, an aspect ratio (depth/width) of not more than 0.7.

In this manner, in order to fill the interconnection groove having an aspect ratio of not more than 0.35 or not more than 0.7 with the plating Cu film, it is necessary to form a further thicker Cu film, with the result that the step difference on the surface of the Cu film becomes further greater. In contrast, when the unevenness are formed on the bottom of each of these interconnection grooves, it becomes possible to reduce the step difference on the surface of the Cu film by the effects as described in the first and second embodiments. In other words, by forming the concave and convex portions on the bottom of each of the interconnection grooves having an aspect ratio of not more than 0.35 or not more than 0.7, it is possible to fill the groove by using a thinner plating Cu film, and consequently to reduce the step difference on the surface of the Cu film.

(Fourth Embodiment)

The inventors, etc., of the present invention carried out an examination on the relationship between the plating Cu film thickness and the groove width used for the unevenness in the case when the groove-shaped unevenness were formed.

Groove-shaped unevenness having widths in the range of 0.26 to 2 μm were formed, and Cu films were formed on the unevenness by plating; and the results are listed on Table 4.

TABLE 4
Relationship between Cu plating film thickness and groove width

| | Cu film thickness (μm) | |
|---|---|---|
| Groove width (μm) | Plating current 5A | Plating current 8A |
| 0.26 | 1.1 | 1 |
| 0.3 | 1.1 | 1 |
| 0.34 | 1.05 | 1 |
| 0.4 | 1.05 | 1 |
| 0.5 | 1 | 0.9 |
| 0.7 | 1 | 0.4 |
| 1 | 0.95 | 0.4 |
| 1.4 | 0.43 | 0.4 |
| 2 | 0.43 | 0.4 |

In this case, the depth of the grooves was 0.5 μm, and the pitch was 4 times the groove width. On this was formed a TaN film as the barrier metal by sputtering, with a thickness of 20 nm, and was further formed a Cu film as a seed layer for a plating film by sputtering, with a thickness of 150 nm. Next, an electrolytic plating process was carried out so that a Cu film having a thickness of 400 nm was formed. The current at this time was set to 5A or 8A. When the plating current was 5A, it was not possible to obtain any effect for improving the film-forming rate in the case of a groove width of not less than 1.4 μm, that is, an aspect ratio (depth/width) of not more than 0.35. Moreover, when the plating current was 8A, it was not possible to obtain any effect for improving the film-forming rate in the case of a groove width of not less than 0.7 μm, that is, an aspect ratio (depth/width) of not more than 0.7.

As described above, in order to improve the film-forming rate, the groove-shaped unevenness formed on the bottom portion of the interconnection groove need to have an aspect ratio of greater than 0.35 or greater than 0.7. Moreover, as the aspect ratio becomes greater, the film-forming rate is further improved; therefore, it is preferable to set the aspect ratio of the groove-shaped unevenness on the bottom portion of the interconnection groove to a greater value.

(Fifth Embodiment)

The inventors, etc., of the present invention carried out an examination on the relationship between the plating Cu film thickness and the hole-diameter used for the unevenness in the case when the hole-shaped unevenness were formed.

Hole-shaped unevenness having widths in the range of 0.26 to 2 μm were formed, and Cu films were formed on the unevenness by plating; and the results are listed on Table 5.

TABLE 5
Relationship between Cu plating film thickness and hole-diameter

| | Cu film thickness (μm) | |
|---|---|---|
| Hole diameter (μm) | Plating current 5A | Plating current 8A |
| 0.26 | 1.2 | 1.1 |
| 0.3 | 1.2 | 1.1 |
| 0.34 | 1.15 | 1.1 |
| 0.4 | 1.1 | 1.1 |
| 0.5 | 1.05 | 1 |
| 0.7 | 1 | 0.4 |
| 1 | 0.95 | 0.4 |
| 1.4 | 0.43 | 0.4 |
| 2 | 0.43 | 0.4 |

In this case, the depth of the holes was 0.5 μm, and the pitch was 4 times the hole diameter. On this was formed a TaN film as the barrier metal by sputtering, with a thickness of 20 nm, and was further formed a Cu film as a seed layer for a plating film by sputtering, with a thickness of 150 nm. Next, an electrolytic plating process was carried out so that a Cu film having a thickness of 400 nm was formed. The current at this time was set to 5A or 8A. When the plating current was 5A, it was not possible to obtain any effect for improving the film-forming rate in the case of a hole diameter of not less than 1.4 μm, that is, an aspect ratio (depth/diameter) of not more than 0.35. Moreover, when the plating current was 8A, it was not possible to obtain any effect for improving the film-forming rate in the case of a hole diameter of not less than 0.7 μm, that is, an aspect ratio (depth/diameter) of not more than 0.7.

As described above, in order to improve the film-forming rate, the hole-shaped unevenness formed on the bottom portion of the interconnection groove need to have an aspect ratio of greater than 0.35 or greater than 0.7. Moreover, as the aspect ratio becomes greater, the film-forming rate is further improved; therefore, it is preferable to set the aspect ratio of the hole-shaped unevenness on the bottom portion of the interconnection groove to a greater value.

Moreover, the hole-shaped unevenness are more effective in improving the plating rate than the groove-shaped unevenness.

(Sixth Embodiment)

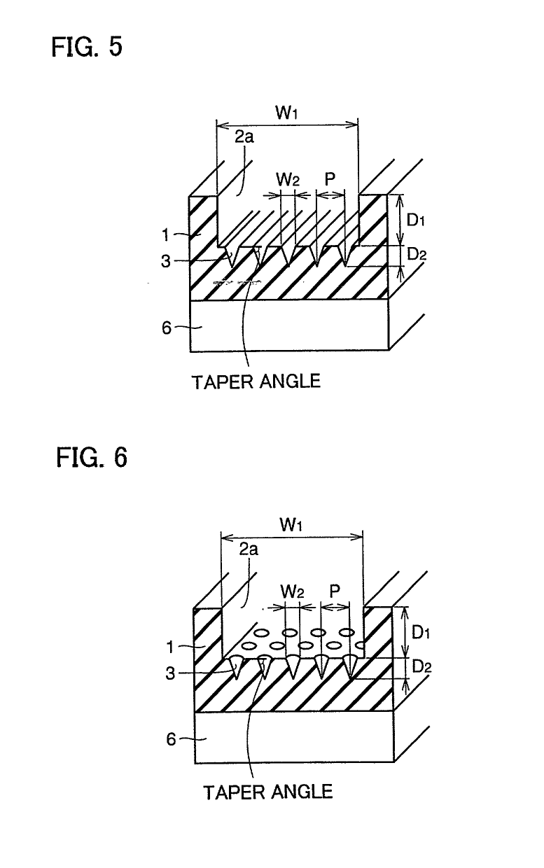

Referring to FIGS. 4 and 5, in comparison with the structure of the first embodiment, the structure in accordance with the present embodiment is different in the shape of unevenness 3 formed on the bottom of the interconnection groove 2a. In the present embodiment, the unevenness 3 are constituted by a plurality of grooves each of which has a tapered shape in its cross-section, and two side walls of the groove for use in the concave and convex portions are designed to cross each other.

The widths W1 of the respective interconnection grooves were set to, for example, 0.5, 5, 10 and 20 μm, and the depth D1 was set to 0.7 μm. A plurality of grooves serving as the unevenness 3, which have a triangular shape in their cross-section, were formed on the bottom surface of each interconnection groove 2a having the width W1 of not less than 5 μm. The width W2 of the groove for use in the unevenness was set to, for example, 0.35 μm, the depth D2 was, for example, 0.3 μm, the tapered angle was, for example, 60 degrees, and the pitch P was, for example, 1 μm.

Here, the other structures except for the above-mentioned structure are virtually the same as those of the first embodiment; therefore, the same members are indicated by the same reference numbers, and the description thereof is omitted.

The unevenness 3, constituted by the grooves having a tapered shape in their cross-section, were formed by adjusting etching conditions as described below.

Etching gas is decomposed in plasma to cause a competitive reaction between etching in the insulating film and the deposition of the product. The etching seed* is accelerated in a direction perpendicular to the substrate, and made incident thereon; therefore, on the bottom surface of the groove, etching is mainly exerted so that an etching process takes place. In contrast, on the side faces, the deposition of the product is mainly exerted. The product serves so as to protect the side faces from the etching seed. In the case when the etching conditions are adjusted so as to easily form the product, as the etching of the groove proceeds, the deposition of the product increases, with the result that the side faces have a tapered shape. When the etching gas or additive gas has a high content of C, the deposition of the product comes to have a high rate. For example, with respect to the etching gas, a gas containing much C such as C₄F₈, rather than CHF₃, is more likely to provide the tapered shape. Moreover, it is also effective to add a gas containing C, such as CO, as the additive gas.

Here, the other manufacturing methods except for the above-mentioned method are virtually the same as those of the first embodiment; therefore, the description thereof is omitted.

The inventors, etc., of the present invention carried out an examination on the effects of the formation of the unevenness constituted by such tapered grooves on the bottom of the interconnection groove.

First, in accordance with the above-mentioned method, a plurality of grooves having a triangular shape in their cross-section were formed on the bottom of the interconnection groove as the unevenness 3, with a width W2 of 0.35 μm, a depth D2 of 0.3 μm and a tapered angle of 60 degrees, in a manner so as to have a pitch P of 1 μm. On this was formed a TaN film as the barrier metal by sputtering, with a thickness of 20 nm, and was further formed a Cu film as a seed layer for a plating film by sputtering, with a thickness of 150 nm. Next, an electrolytic plating process was carried out in a plating solution of a copper sulfate bath so that a Cu film was formed until it had been embedded in the interconnection grooves. The current for the electrolytic plating was set to 5A. For comparative purposes, the same structure without the unevenness (grooves) on the bottom of the interconnection groove was formed in the same manner.

With respect to the substrate formed as described above, Table 6 shows the film thickness of the Cu film formed on each of the portions of the interconnection grooves and flat portions without the grooves. Here, the film thickness represents a value including the thickness of the Cu film serving as the seed layer.

TABLE 6
Effects of formation of unevenness constituted by tapered grooves
on the bottom of a interconnection groove

Cu film thickness (μm)

| Interconnection width | Without unevenness | With unevenness |
|---|---|---|
| (μm) | 800 nm plating | 400 nm plating |
| 0.5 | 2 | 1.05 |
| 5 | 0.7 | 0.8 |
| 10 | 0.7 | 0.8 |
| 20 | 0.7 | 0.8 |
| Flat portion | 0.7 | 0.3 |
| (from groove bottom) | (1.4) | (1.0) |

The amount of plating required for filling the interconnection groove was 400 nm in the case of the presence of the unevenness (grooves) on the bottom of the interconnection groove, and was 800 nm in the case of the absence of the unevenness (grooves) on the bottom of the interconnection groove. In the case of the absence of the unevenness (grooves) on the bottom of the interconnection groove, the highest portion of the surface of the Cu film was a interconnection portion having a width of 0.5 μm while the lowest portion was each of interconnection portions having widths of 0.5, 10 and 20 μm, and the step difference was 1.3 μm. In contrast, in the case of the presence of the unevenness (grooves) on the bottom of the interconnection groove, the highest portion of the surface of the Cu film was a interconnection portion having a width of 0.5 μm while the lowest portion was each of interconnection portions having widths of 5, 10 and 20 μm, and the step difference was 0.25 μm.

As described above, by forming the unevenness (grooves) on the bottom of the interconnection, the surface step difference was greatly reduced from 1.3 μm to 0.25 μm at the time when the interconnection grooves had been filled with the plating Cu film.

The reason for the reduction in the amount of plating required for filling the interconnection grooves was that the plating rate was increased by forming the groove-shaped unevenness on the bottom of the interconnection groove. The mechanism of improving the plating rate is based upon the same principle as described in the first embodiment.

Moreover, since the grooves for the unevenness are formed into a tapered shape, it is possible to improve the depositing rate of plating, and also to make the depth of the groove shallower, as compared with the normal groove-shaped unevenness.

(Seventh Embodiment)

Referring to FIGS. 4 and 6, in the structures of the present embodiment, the shape of the unevenness 3 formed on the bottom surface of the interconnection groove 2a is different from that of the sixth embodiment. In the present embodiment, the unevenness 3 are constituted by a plurality of holes having a tapered shape in their cross-section, and the two side faces of each hole for used in the unevenness are allowed to cross each other in the cross-section.

The widths W1 of the respective interconnection grooves were set to, for example, 0.5, 5, 10 and 20 μm, and the depth D1 was set to 0.7 μm. A plurality of cone-shaped holes serving as the unevenness 3 were formed on the bottom surface of each interconnection groove 2a having the width W1 of not less than 5 μm. The aperture diameter W2 of the hole for use in the unevenness was set to, for example, 0.35 μm, the depth D2 was, for example, 0.3 μm, the tapered angle was, for example, 60 degrees, and the pitch P was, for example, 1 μm.

Here, the other structures except for the above-mentioned structure are virtually the same as those of the sixth embodiment; therefore, the same members are indicated by the same reference numbers, and the description thereof is omitted.

The manufacturing method of the present embodiment is virtually the same as the manufacturing method of the sixth embodiment; therefore, the description thereof is omitted. Here, the formation method of the tapered holes is virtually the same as the formation method of the tapered grooves in the sixth embodiment.

The inventors, etc., of the present invention carried out an examination on the effects of the formation of the unevenness constituted by such tapered holes on the bottom of the interconnection groove.

First, in accordance with the above-mentioned method, a plurality of cone-shaped holes were formed on the bottom of the interconnection groove as the unevenness 3, with an aperture diameter W2 of 0.35 μm, a depth D2 of 0.3 μm and a tapered angle of 60 degrees, in a manner so as to have a pitch P of 1 μm. On this was formed a TaN film as the barrier metal by sputtering, with a thickness of 20 nm, and was further formed a Cu film as a seed layer for a plating film by sputtering, with a thickness of 150 nm. Next, an electrolytic plating process was carried out in a plating solution of a copper sulfate bath so that a Cu film was formed until it had been embedded in the interconnection grooves. The current for the electrolytic plating was set to 5A. For comparative purposes, the same structure without the unevenness (holes) on the bottom of the interconnection groove was formed in the same manner.

With respect to the substrate formed as described above, Table 7 shows the film thickness of the Cu film formed on each of the portions of the interconnection grooves and flat portions without the grooves. Here, the film thickness represents a value including the thickness of the Cu film serving as the seed layer.

TABLE 7
Effects of formation of unevenness constituted by tapered holes
on the bottom of a interconnection groove

Cu film thickness (μm)

| Interconnection width | Without unevenness | With unevenness |
|---|---|---|
| (μm) | 800 nm plating | 400 nm plating |
| 0.5 | 2 | 1.05 |
| 5 | 0.7 | 0.85 |
| 10 | 0.7 | 0.85 |
| 20 | 0.7 | 0.85 |
| Flat portion | 0.7 | 0.3 |
| (from groove bottom) | (1.4) | (1.0) |

The amount of plating required for filling the interconnection groove was 400 nm in the case of the presence of the unevenness (holes) on the bottom of the interconnection groove, and was 800 nm in the case of the absence of the unevenness (holes) on the bottom of the interconnection groove. In the case of the absence of the unevenness (holes) on the bottom of the interconnection groove, the highest portion of the surface of the Cu film was a interconnection portion having a width of 0.5 μm while the lowest portion was each of interconnection portions having widths of 5, 10 and 20 μm, and the step difference was 1.3 μm. In contrast, in the case of the presence of the unevenness (holes) on the bottom of the interconnection groove, the highest portion of the surface of the Cu film was a interconnection portion having a width of 0.5 μm while the lowest portion was each of interconnection portions having widths of 5, 10 and 20 μm, and the step difference was 0.2 μm.

As described above, by forming the unevenness (holes) on the bottom of the interconnection, the surface step difference was greatly reduced from 1.3 μm to 0.2 μm at the time when the interconnection grooves had been filled with the plating Cu film.

The reason for the reduction in the amount of plating required for filling the interconnection grooves was that the plating rate was increased by forming the groove-shaped unevenness on the bottom of the interconnection groove. The mechanism of improving the plating rate is based upon the same principle as described in the first embodiment.

Moreover, since the holes for the unevenness are formed into a cone-shape, it is possible to improve the depositing rate of plating, and also to make the depth of the hole shallower, as compared with the column-shaped holes for unevenness.

(Eighth Embodiment)

The inventors, etc., of the present invention carried out an examination on the relationship between the plating Cu film thickness and the taper angle of the unevenness constituted by tapered grooves.

Referring to FIG. 5, unevenness 3, constituted by grooves having triangular shapes in their cross-section with taper angles in the range of 20 to 60 degrees, were formed, and Cu films were formed on the unevenness 3 by plating, and the results are listed on Table 8.

TABLE 8
Relationship between Cu plating film thickness and taper angles of
unevenness constituted by tapered grooves

| Taper angle (degrees) | Cu film thickness (μm) |
|---|---|
| 20 | 0.4 |
| 30 | 0.65 |
| 45 | 1.15 |
| 60 | 1.25 |

Referring to FIG. 5, the depth D1 of the groove 2a was 0.5 μm, and on this was formed a TaN film as the barrier metal by sputtering, with a thickness of 20 nm, and was further formed a Cu film as a seed layer for a plating film by sputtering, with a thickness of 150 nm. Further, a Cu film was formed by electrolytic plating with a thickness of 400 nm. The current for the electrolytic plating was set to 5A.

In the case of the grooves having taper angles of not more than 20 degrees, it was not possible to obtain any effect for improving the plating rate. Consequently, the taper angle needs to be greater than 20 degrees. Moreover, as the taper angle becomes greater, the effect for improving the plating rate becomes greater, and, in particular, the effect is remarkable when the taper angle is not less than 45 degrees; therefore, it is preferable to make the taper angle greater, and it is more preferable to set it to not less than 45 degrees.

(Ninth Embodiment)

The inventors, etc., of the present invention carried out an examination on the relationship between the plating Cu film thickness and the taper angle of the unevenness constituted by cone-shaped holes.

Referring to FIG. 6, unevenness, constituted by cone-shaped holes having taper angles in the range of 20 to 60 degrees, were formed, and Cu films were formed on the unevenness by plating, and the results are listed on Table 9.

TABLE 9
Relationship between Cu plating film thickness and taper angles of
unevenness constituted by cone-shaped holes.

| Taper angle (degrees) | Cu film thickness (μm) |
|---|---|
| 20 | 0.4 |
| 30 | 0.75 |
| 45 | 1.2 |
| 60 | 1.35 |

Referring to FIG. 6, the depth D1 of the hole was 0.5 μm, and on this was formed a TaN film as the barrier metal by sputtering, with a thickness of 20 nm, and was further formed a Cu film as a seed layer for a plating film by sputtering, with a thickness of 150 nm. Further, a Cu film was formed by electrolytic plating with a thickness of 400 nm. The current for the electrolytic plating was set to 5A.

In the case of the holes having taper angles of not more than 20 degrees, it was not possible to obtain any effect for improving the plating rate. Consequently, the taper angle needs to be greater than 20 degrees. Moreover, as the taper angle becomes greater, the effect for improving the plating rate becomes greater, and, in particular, the effect is remarkable when the taper angle is not less than 45 degrees; therefore, it is preferable to make the taper angle greater, and it is more preferable to set it to not less than 45 degrees.

(Tenth Embodiment)

In the sixth embodiment, an explanation has been given of a case in which, in order to form unevenness constituted by tapered grooves, an etching process that forms the side faces into a tapered shape is used; and in this case, sub-trenches that are formed at the time of etching may be utilized.

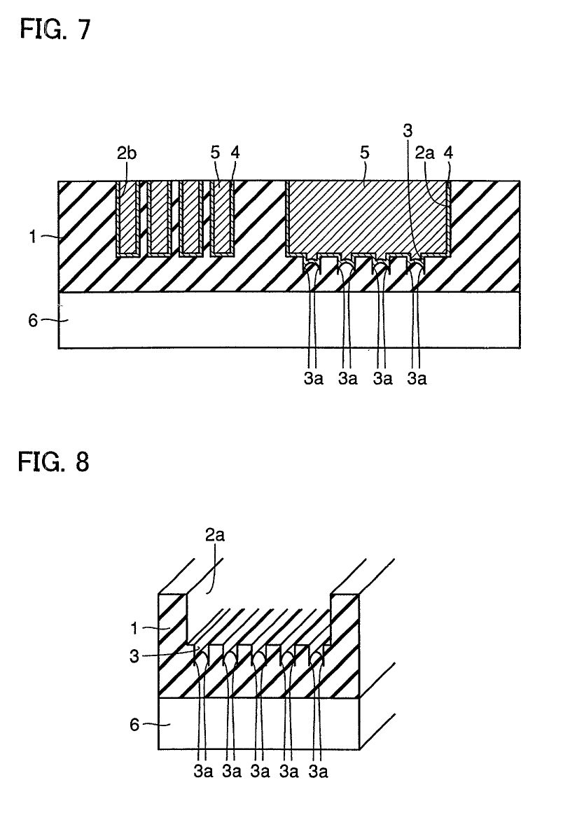

Referring to FIGS. 7 and 8, in comparison with the structure of the sixth embodiment, the structure of the present embodiment is different in the shape of the unevenness 3. The present embodiment has a structure in which sub-trenches 3a are formed on both of the side faces of each groove-shaped concave portion of the unevenness 3. Consequently, each concave portion of the unevenness 3 has a bottom surface that is raised in the center portion.

The other structures except for the above-mentioned structure are the same as the structures of the above-mentioned sixth embodiment; therefore, the same members are indicated by the same reference numbers, and the description thereof is omitted.

Various theories as described below are given with respect to the mechanism by which these sub-trenches 3a are generated.

(1) Ions, which exert an etching reaction, are directed in a direction perpendicular to the substrate, and made incident on the substrate due to the substrate electric potential. Here, there are some ions that are made incident with slight inclinations with a certain distribution. When these ions are allowed to collide with a side face of the concave portion, they are reflected by this and reach the substrate. Since the ion orbit is only slightly inclined in the vertical direction, the etching contribution becomes greater in the vicinity of the side wall of the bottom surface due to such reflected ions. Consequently, the etching rate becomes higher in the vicinity of the side wall, thereby causing a sub-trench 3a.

(2) When resist is charged up by electrons, the ion orbit that is made incident perpendicularly on the substrate is bent toward the resist side due to the electric field. However, at this time, the bent in the orbit is very small because the mass of an ion is great. Consequently, the etching rate becomes higher in the vicinity of the side wall, thereby causing a sub-trench 3a.

(3) Competitive reactions occur between etching and deposition during an etching process. On the side wall portion, since the deposition reaction is predominant with fewer incident ions, the deposition occurs in a manner so as to protect the side wall. In contrast, on the bottom portion, since there are greater incident ions, etching takes place. Since such a deposition reaction is weak on the bottom portion in the vicinity of the side wall and since the resulting deposition film is weak at this portion, the etching rate becomes greater, in particular, at this portion, thereby causing a sub-trench 3a.

As described above, typical conditions for obtaining greater sub-trenches 3a are described as follows: in a standard condition (10⁵ Pa, 25° C.), gas is set to CHF₃/Ar/O₂=20/200/10 cm³/ min., pressure is 2.7 Pa, and power is 1000 W; and in this state, the power is raised with the pressure being reduced, it becomes easier to produce sub-trenches 3a.

By utilizing the sub-trenches 3a generated as described above, unevenness 3, constituted by tapered grooves as illustrated in FIGS. 7 and 8, are obtained, and the same effects as the sixth embodiment are available.

Moreover, since two sub-trenches 3a are formed in one groove for the unevenness, it is possible to make the pitch of the unevenness 3a, and consequently to improve the plating rate, as will be described later.

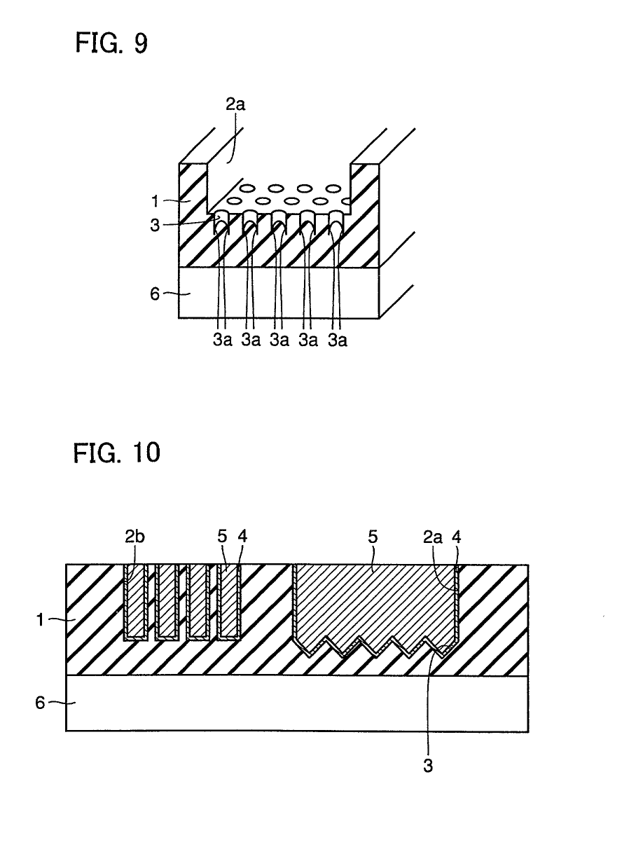

FIG. 9 is a perspective view that shows an example in which the sub-trenches are utilized in unevenness 3 constituted by a plurality of holes. In this case, a sub-trench 3a is formed in an annular shape along the edge of the bottom portion of each hole for the unevenness, and the same effects as the seventh embodiment are obtained. Since the sub-trench 3a is formed in an annular shape with respect to one hole, it is possible to increase the density on the portion in which the taper is formed; thus, it is possible to increase the effects for increasing the plating rate as will be described later.

(Eleventh Embodiment)

The inventors, etc., of the present invention carried out an examination on the relationship between the pitches P of the grooves and the plating Cu film thickness in the unevenness 3 constituted by tapered grooves shown in FIGS. 4 and 5.

Unevenness 3, constituted by grooves having a groove width W2 of 0.4 μm and a depth D2 of 0.5 μm, were formed with pitches P in the range of 0.6 to 4 μm, and a Cu film was formed on the unevenness 3 by plating; and the results are listed on Table 10.

TABLE 10
Relationship between Cu plating film thickness and pitches of
unevenness constituted by grooves

| Pitch (μm) | Cu film thickness (μm) |
|---|---|
| 0.6 | 1.35 |
| 0.8 | 1.25 |
| 1 | 1.15 |
| 1.6 | 1.05 |
| 4 | 0.6 |

On these unevenness 3 was formed a TaN film as the barrier metal by sputtering, with a thickness of 20 nm, and was further formed a Cu film as a seed layer for a plating film by sputtering, with a thickness of 150 nm. Further, a Cu film was formed thereon by electrolytic plating with a thickness of 400 nm. The current for the electrolytic plating was set to 5A.

As the pitch P of the grooves for the unevenness 3 is increased, the effect of the unevenness for improving the plating rate decreases. In the case when the pitch P is not more than 1.6 μm, that is, the pitch P is not more than 4 times the groove width W2, a Cu film of 0.4 μm is formed by electrolytic plating to fill the groove having the depth D2 of 0.5 μm, and on this is further formed a film as thick as 0.7 μm.

However, in the case when the pitch P is greater than 1.6 μm, that is, the pitch P is greater than 4 times the groove width W2, the effect for improving the plating rate is extremely small, with the result that when a Cu film of 0.4 μm is formed by electrolytic plating, it is only possible to fill the groove of 0.5 μm for the unevenness.

As described above, the pitch P needs to be set to a value not more than 4 times the groove width W2. The smaller the pitch P, the greater the effect for improving the plating rate; therefore, it is preferable to make the pitch P smaller.

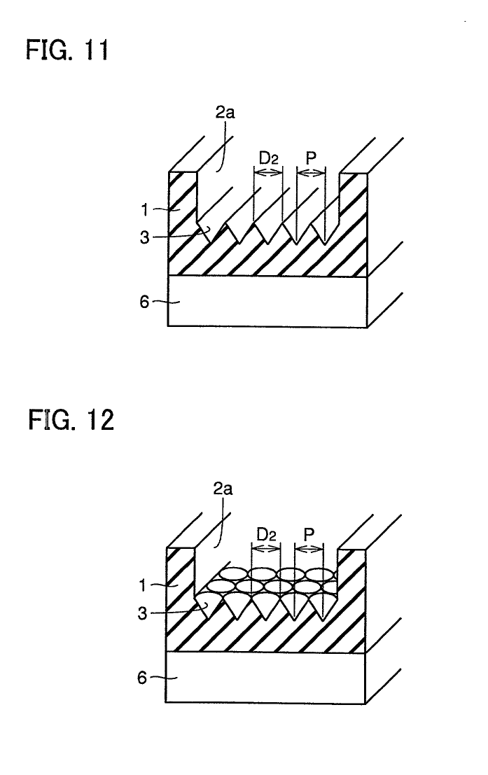

As illustrated in FIG. 10 and FIG. 11, in the case when the unevenness 3, constituted by tapered grooves described in the eighth embodiment, are formed, the pitch P of the groove for the unevenness is set to the groove width D2 so that the pitch P is minimized with respect to the groove width W2; consequently, this arrangement is very effective for improving the plating rate.

Moreover, the inventors, etc., of the present invention carried out an examination on the relationship between the pitches P of the holes and the plating Cu film thickness in the unevenness 3 constituted by tapered holes shown in FIG. 6.

Unevenness 3, constituted by holes having a hole diameter W2 of 0.4 μm and a depth D2 of 0.5 μm, were formed with pitches P in the range of 0.6 to 4 μm, and a Cu film was formed on the unevenness 3 by plating; and the results are listed on Table 11.

TABLE 11
Relationship between Cu plating film thickness and pitches of
unevenness constituted by holes

| Pitch (μm) | Cu film thickness (μm) |
|---|---|
| 0.6 | 1.4 |
| 0.8 | 1.3 |
| 1 | 1.25 |
| 1.6 | 1.1 |
| 4 | 0.6 |

On these unevenness 3 was formed a TaN film as the barrier metal by sputtering, with a thickness of 20 nm, and was further formed a Cu film as a seed layer for a plating film by sputtering, with a thickness of 150 nm. Further, a Cu film was formed thereon by electrolytic plating with a thickness of 400 nm. The current for the electrolytic plating was set to 5A.

As the pitch P of the holes for the unevenness is increased, the effect of the unevenness 3 for improving the plating rate decreases. In the case when the pitch P is not more than 1.6 μm, that is, the pitch P is not more than 4 times the hole diameter W2, a Cu film of 0.4 μm is formed by electrolytic plating to fill the groove having the depth D2 of 0.5 μm, and on this is further formed a film as thick as 0.7 μm.

However, in the case when the pitch P is greater than 1.6 μm, that is, the pitch P is greater than 4 times the hole diameter W2,the effect for improving the plating rate is extremely small, with the result that when a Cu film of 0.4 μm is formed by electrolytic plating, it is only possible to fill the groove of 0.5 μm for the unevenness.

As described above, the pitch P needs to be set to a value not more than 4 times the hole diameter W2. The smaller the pitch P, the greater the effect for improving the plating rate; therefore, it is preferable to make the pitch P smaller.

As illustrated in FIG. 12, in the case when the unevenness 3, constituted by tapered holes described in the ninth embodiment, are formed, the pitch P of the holes for the unevenness is set to the groove width D2 so that the pitch P is minimized with respect to the hole diameter W2; consequently, this arrangement is very effective for improving the plating rate.

(Twelfth Embodiment)

In this embodiment, an explanation will be given of a manufacturing method of a semiconductor device shown in FIG. 1.

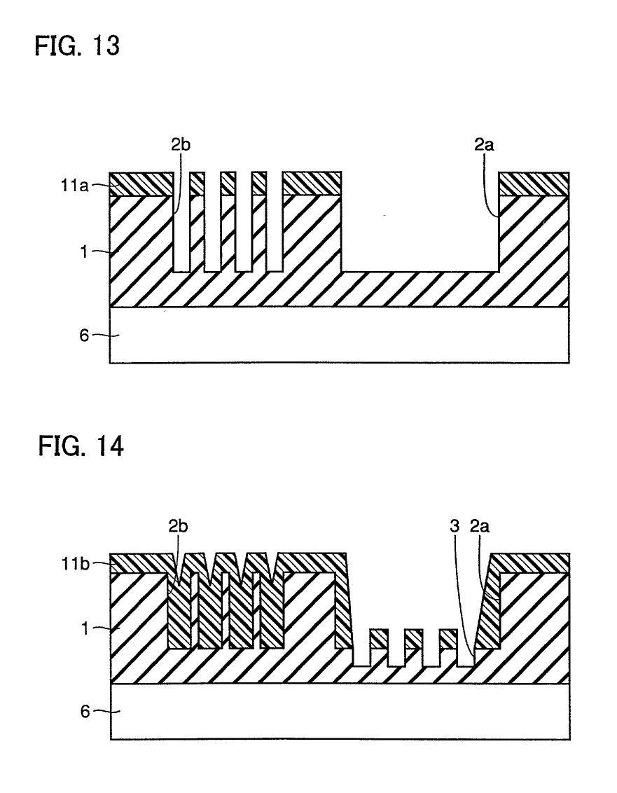

First, referring to FIG. 13, an insulating film 1 is formed on a semiconductor substrate or a lower insulating film 6. A resist pattern 11a bearing a interconnection pattern formed therein is formed on the insulating film 1 by a photolithographic technique. The insulating film 1 is subjected to a reactive ion etching process using the resist pattern 11a as a mask; thus, interconnection grooves 2a, 2b, used for interconnection, are formed in the insulating film 1 with a depth of, for example, 0.7 μm. Thereafter, the resist pattern 11a is removed by, for example, ashing.

Referring to FIG. 14, a resist pattern 11b in which a groove pattern having a width of 0.4 μm and a space of 0.6 μm is formed as a pattern for groove-shaped unevenness is formed on the insulating film 1 by a photolithographic technique. The insulating film 1 is subjected to a reactive ion etching process using the resist pattern 11b as a mask. Consequently, unevenness 3, constituted by a plurality of grooves having a depth of, for example, 0.5 μm, are formed only on the bottom portion of each of the interconnection grooves 2a having a width of 5 μm. Thereafter, the resist pattern 11b is removed by, for example, ashing.

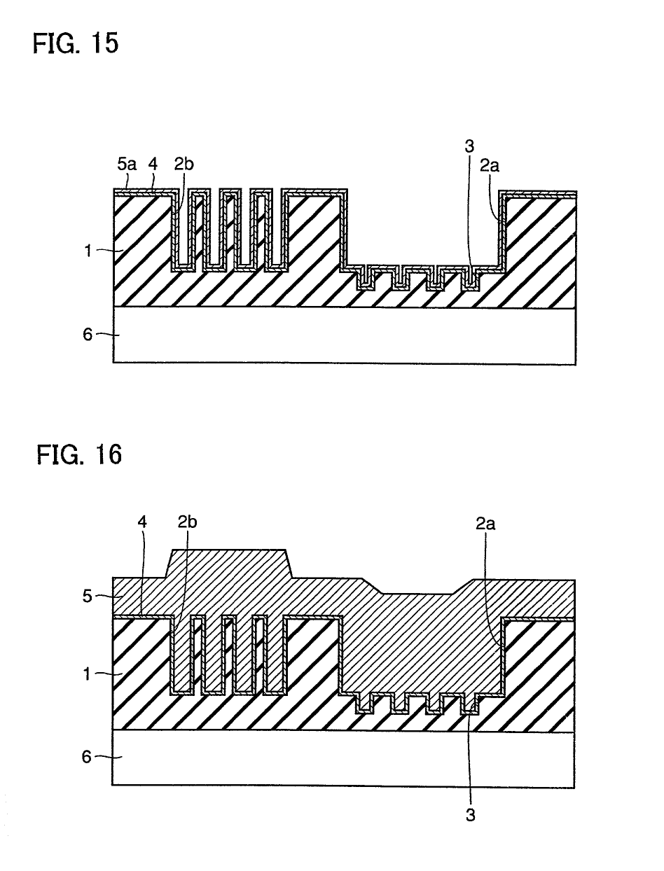

Referring to FIG. 15, for example, a TaN film is formed on the insulating film 1 as barrier metal 4 by sputtering, with a thickness of 20 nm, and, for example, a Cu film is formed thereon as a seed layer 5a for a plating film by sputtering, with a thickness of 150 nm.

Referring to FIG. 16, an electrolytic plating process is carried out in a plating solution of a copper sulfate bath so that the Cu film 5 is formed until it has been embedded in the interconnection grooves 2a, 2b. The current for the electrolytic plating is set to, for example, 5A. Thereafter, the Cu film 5 and the barrier metal 4 are abraded and removed by the CMP method until at least the upper surface of the insulating film 1 has been exposed. Thus, as illustrated in FIG. 1, the Cu film 5 and the barrier metal 4 are allowed to remain only in the interconnection grooves 2a, 2b as interconnection.

In the present embodiment, as described in the first embodiment, groove-shaped unevenness 3 are formed only on the bottom portion of each of the wide interconnection grooves 2a so that it is possible to improve the plating rate, and also to make irregularities on the surface of the Cu film 5 after having been subjected to the plating. As a result, it becomes possible to reduce overpolishing that tends to occur upon carrying out the CMP method, and also to reduce a dent on the upper surface of each of the wide wires; thus, the resulting effect is that, even in the case of wide wires, a low resistivity is achieved with less deviation in resistance.

With respect to the semiconductor device having the structure as shown in FIG. 1 manufactured by the method of the present embodiment, the inventors, etc., of the present invention carried out an examination on the sheet resistivity of the interconnection and the dispersion (1σ) in the interconnection resistance. The results of these are listed on Table 12. Here, for comparative purposes, the results of a case in which no unevenness 3 are placed on the bottom portion of the wire are also listed.

TABLE 12
Sheet resistivity of interconnection and dispersion in interconnection
resistance in the case of addition of unevenness

| | Resistivity of | | Dispersion (%) | |
|---|---|---|---|---|
| | interconnection | | of interconnection | |
| | sheet (Ω/□) | | resistance | |
| Groove width | With | Without | With | Without |
| (μm) | unevenness | unevenness | unevenness | unevenness |
| 0.5 | 0.044 | 0.046 | 2.2 | 6.2 |
| 5 | 0.047 | 0.056 | 3.3 | 12.7 |
| 10 | 0.048 | 0.06 | 3.3 | 15.5 |
| 20 | 0.048 | 0.062 | 3.5 | 16.7 |

The results of Table 12 show that, by placing the unevenness 3 on the bottom portion of the wire, it becomes possible to provide a wire having a low resistivity with less deviation in resistance.

Here, in the present embodiment, an explanation has been given of an example in which unevenness 3 constituted by a plurality of grooves are formed as the unevenness 3 on the bottom portion of the groove; however, as described in the second embodiment, the unevenness 3 constituted by a plurality of holes may be formed, or as described in the sixth, seventh and tenth embodiments, the unevenness 3 constituted by a plurality of tapered grooves or holes may be formed, and in any of these cases, it becomes possible to obtain the same effects as those of the present embodiment.

Moreover, the insulating film 1 may be divided into two upper and lower layers, and an etching stopper layer may be placed between the two layers.

(Thirteenth Embodiment)

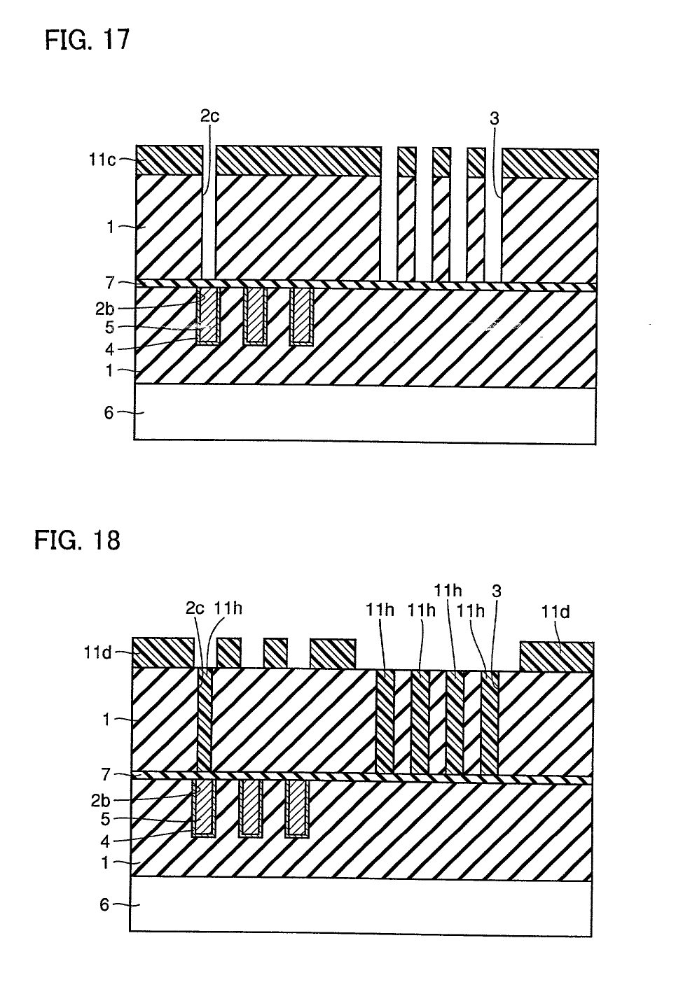

First, referring to FIG. 17, an insulating film 1 is formed on a semiconductor substrate or a lower insulating film 6. Interconnection grooves 2b are formed on this insulating film 1, and lower-layer wires, constituted by a barrier metal 4 and a conductive layer 5, are formed so as to be embedded in the interconnection grooves 2b.

On these lower-layer wires 4, 5 is formed an SiN film (silicon nitride film) having a thickness of, for example, 100 nm, by a plasma CVD (Chemical Vapor Deposition) method as an etching stopper layer 7. On this etching stopper layer 7 is formed an SiO₂ film (silicon oxide film) having a thickness of, for example, 1.3 μm, by a plasma CVD method as an insulating film 1. These etching stopper layer 7 and insulating film 1 are formed as interlayer insulating films.

A resist pattern 11c having a pattern of connection holes formed therein is formed on the insulating film 1 by a photolithographic technique. In this photolithographic process, together with the pattern of the connection holes, a groove pattern is simultaneously transferred on the resist pattern 11c along the length direction of the interconnection. This groove pattern is a pattern of groove-shaped unevenness to be formed on the bottom portion of each of the interconnection grooves having a width of not less than 5 μm, and the unevenness have a width of 0.4 82 m and a space of 0.6 82 m. The insulating film 1 is subjected to a reactive ion etching process by using the resist pattern 11c as a mask until one portion of the surface of the etching stopper layer 7 has been exposed. Thus, the grooves 3, which are to form unevenness simultaneously with the connection holes 2c, are preliminarily formed on the insulating layer 1. Thereafter, the resist pattern 11c is removed by, for example, ashing.

Referring to FIG. 18, SOG (Spin On Glass) 11h is applied onto the insulating film 1 so as to be embedded in the connection holes 2c and the grooves 3 for unevenness. Moreover, a resist pattern 11d having a interconnection pattern formed therein is formed on the insulating film 1 by a photolithographic technique. The insulating film 1 is subjected to a reactive ion etching process by using the resist pattern 11d as a mask.

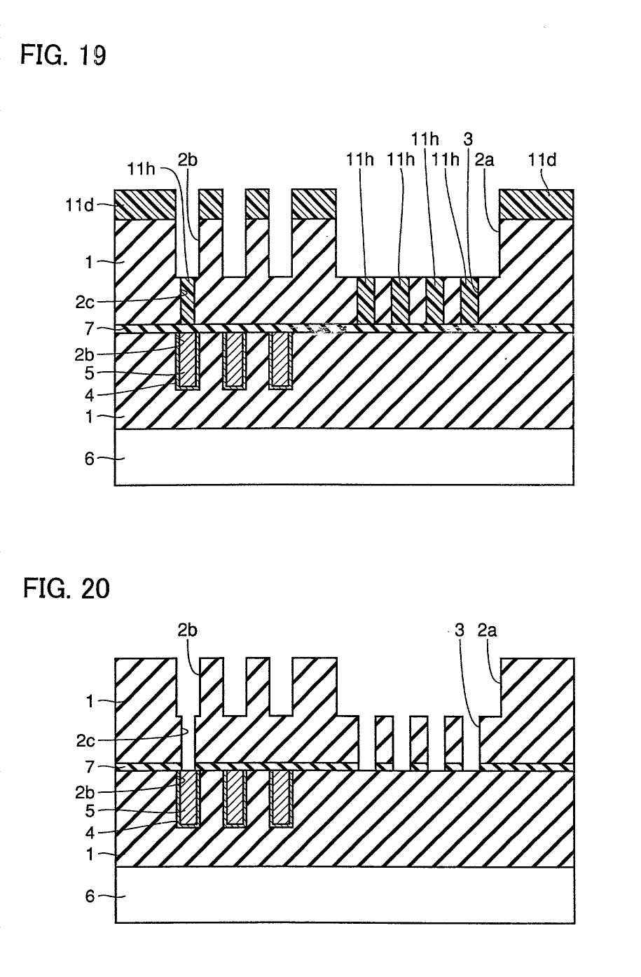

Referring to FIG. 19, the above-mentioned etching process forms interconnection grooves 2a, 2b having a depth of, for example, 0.7 μm on the insulating film 1. Then, the resist pattern 11d is removed by ashing, and the SOG 11h is removed by low-concentration hydrofluoric acid.

Referring to FIG. 20, in order to remove the etching stopper layer 7 exposed from the connection holes 2c and the grooves 3 for unevenness, etching is carried out on the entire surface of the SiN film. Thus, the connection holes 2c to the lower wires 4, 5 and the unevenness 3 constituted by a plurality of grooves are formed.

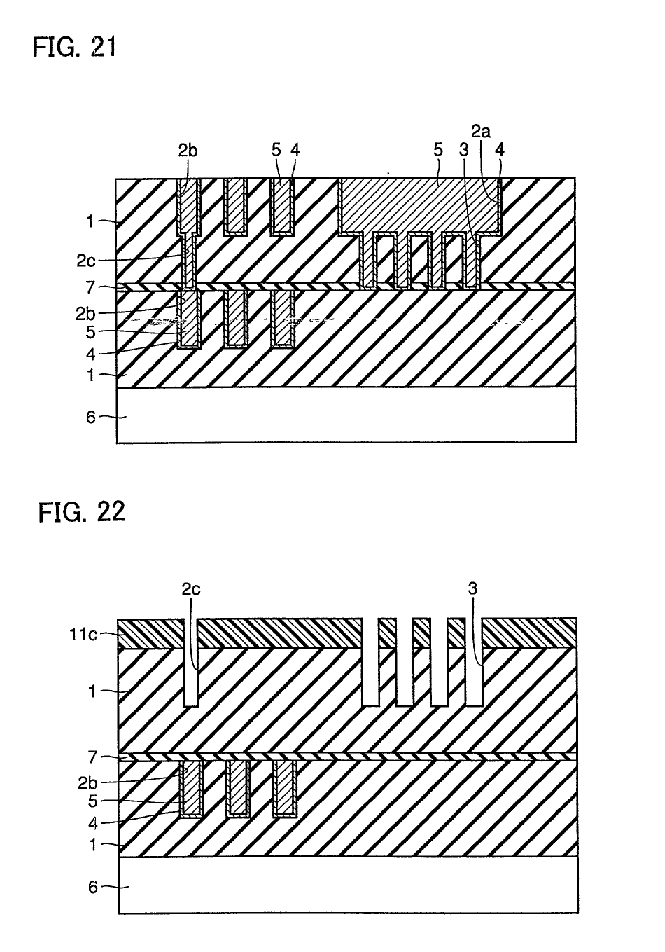

Referring to FIG. 21, for example, a TaN film is formed on the insulating film 1 as barrier metal 4 by sputtering, with a thickness of 20 nm, and, for example, a Cu film is formed thereon as a seed layer for a plating film by sputtering, with a thickness of 150 nm. Then, an electrolytic plating process is carried out in a plating solution of a copper sulfate bath so that the Cu film 5 is formed until it has been embedded in the interconnection grooves 2a, 2b. The current for the electrolytic plating is set to, for example, 5A. Moreover, the Cu film 5 and the barrier metal 4 are abraded and removed by the CMP method until at least the upper surface of the insulating film 1 has been exposed so that wires that are embedded in the interconnection grooves 2a, 2b are formed.

As described above, in the same manner as the twelfth embodiment, the resulting effect is that, even in the case of wide wires, a low resistivity is achieved with less deviation in resistance. Moreover, the unevenness 3 located on the bottom portion of each interconnection groove 2a having a width of not less than 5 μm can be formed simultaneously with the connection holes 2c; therefore, as compared with the twelfth embodiment, it becomes possible to reduce the number of photolithographic, etching and ashing processes.

Here, in the present embodiment, an explanation has been given of an example in which unevenness 3 constituted by a plurality of grooves are formed as the unevenness 3 on the bottom portion of the groove 2a; however, as described in the second embodiment, the unevenness 3 constituted by a plurality of holes may be formed, or as described in the sixth, seventh and tenth embodiments, the unevenness constituted by a plurality of tapered grooves or holes may be formed, and in any of these cases, it becomes possible to obtain the same effects as those of the present embodiment.

Moreover, in the present embodiment, with respect to a material to be injected into the connection holes 2c and the grooves for unevenness 3, the SOG is used in the present embodiment; however, besides the SOG, other organic materials, such as organic SOG and resist, may be used.

Moreover, the etching stopper layer 7 is placed only on the lower-layer wires 4, 5; however, the insulating film 1 may be divided into upper and lower two layers, and an etching stopper layer against etching to the grooves may be interpolated between these two layers.

(Fourteenth Embodiment)

First, referring to FIG. 22, an insulating film 1 is formed on a semiconductor substrate or a lower insulating film 6. Interconnection grooves 2b are formed on this insulating film 1, and lower-layer wires, constituted by a barrier metal 4 and a conductive layer 5, are formed so as to be embedded in the interconnection grooves 2b.

On these lower-layer wires 4, 5 is formed an SiN film having a thickness of, for example, 100 nm, by a plasma CVD method as an etching stopper layer 7. On this etching stopper layer 7 is formed an SiO₂ film having a thickness of, for example, 1.3 μm, by a plasma CVD method as an insulating film 1. These etching stopper layer 7 and insulating film 1 are formed as interlayer insulating films.

A resist pattern 11c having a pattern of connection holes formed therein is formed on the insulating film 1 by a photolithographic technique. In this photolithographic process, together with the pattern of the connection holes, a groove pattern is simultaneously transferred on the resist pattern 11c along the length direction of the interconnection. This groove pattern is a pattern of groove-shaped unevenness to be formed on the bottom portion of each of the interconnection grooves having a width of not less than 5 μm, and the unevenness have a width of 0.4 μm and a space of 0.6 μm. The insulating film 1 is subjected to a reactive ion etching process up to the middle of its film thickness by using the resist pattern 11c as a mask. Thus, the connection holes and the grooves 3 for unevenness are formed. Thereafter, the resist pattern 11c is removed by, for example, ashing.

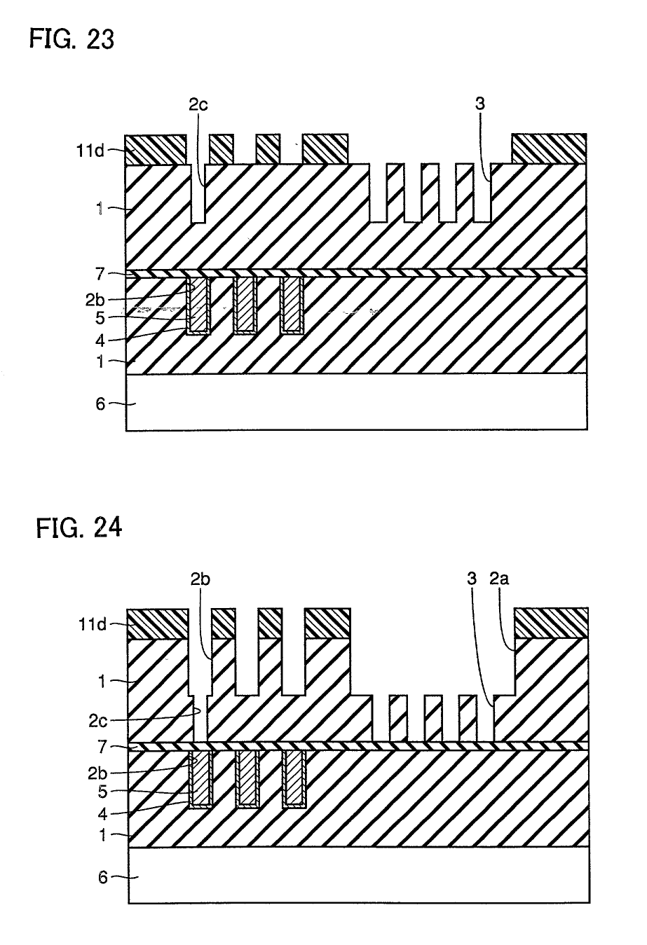

Referring to FIG. 23, a resist pattern 11d having a interconnection pattern formed therein is formed on an insulating film 1 by a photolithographic technique. The insulating film 1 is subjected to a reactive ion etching process using this resist pattern 11d as a mask.

Referring to FIG. 24, the above-mentioned etching process forms interconnection grooves 2a, 2b having a depth of, for example, 0.7 μm on the insulating film 1. At this time, portions of the connection holes 2c and the grooves 3 for unevenness that have been preliminarily formed are also etched until the surface of the etching stopper layer 7 has been exposed. Thereafter, the resist pattern 11d is removed by, for example, ashing.

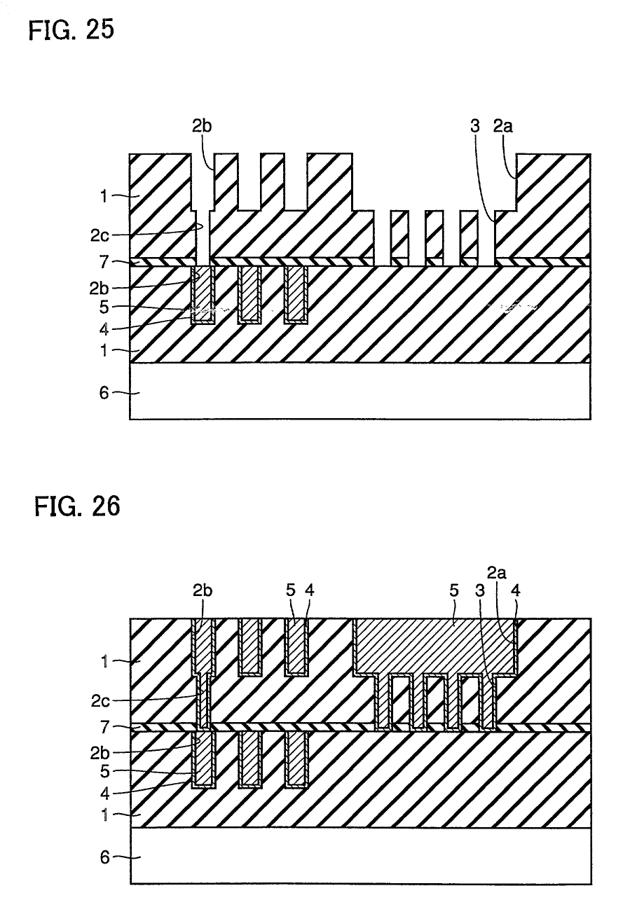

Referring to FIG. 25, in order to remove the etching stopper layer 7 exposed from the connection holes 2c and the grooves 3 for unevenness, etching is carried out on the entire surface of the SiN film. Thus, the connection holes 2c to the lower wires 4, 5 and the unevenness 3 constituted by a plurality of grooves are formed.

Referring to FIG. 26, for example, a TaN film is formed on the insulating film 1 as barrier metal 4 by sputtering, with a thickness of 20 nm, and, for example, a Cu film is formed thereon as a seed layer for a plating film by sputtering, with a thickness of 150 nm. Then, an electrolytic plating process is carried out in a plating solution of a copper sulfate bath so that the Cu film 5 is formed until it has been embedded in the interconnection grooves 2a, 2b. The current for the electrolytic plating is set to, for example, 5A. Moreover, the Cu film 5 and the barrier metal 4 are abraded and removed by the CMP method until at least the upper surface of the insulating film 1 has been exposed so that wires that are embedded in the interconnection grooves 2a, 2b are formed.

As described above, in the same manner as the twelfth embodiment, the resulting effect is that, even in the case of wide wires, a low resistivity is achieved with less deviation in resistance. Moreover, the unevenness 3 located on the bottom portion of each interconnection groove 2a having a width of not less than 5 μm can be formed simultaneously with the connection holes 2c; therefore, as compared with the twelfth embodiment, it becomes possible to reduce the number of photolithographic, etching and ashing processes.

Here, in the present embodiment, an explanation has been given of an example in which unevenness 3 constituted by a plurality of grooves are formed as the unevenness 3 on the bottom portion of the groove 2a; however, as described in the second embodiment, the unevenness 3 constituted by a plurality of holes may be formed, or as described in the sixth, seventh and tenth embodiments, the unevenness constituted by a plurality of tapered grooves or holes may be formed, and in any of these cases, it becomes possible to obtain the same effects as those of the present embodiment.

Moreover, the etching stopper layer 7 is placed only on the lower-layer wires 4, 5; however, the insulating film 1 may be divided into upper and lower two layers, and an etching stopper layer against etching to the grooves may be interpolated between these two layers.

(Fifteenth Embodiment)

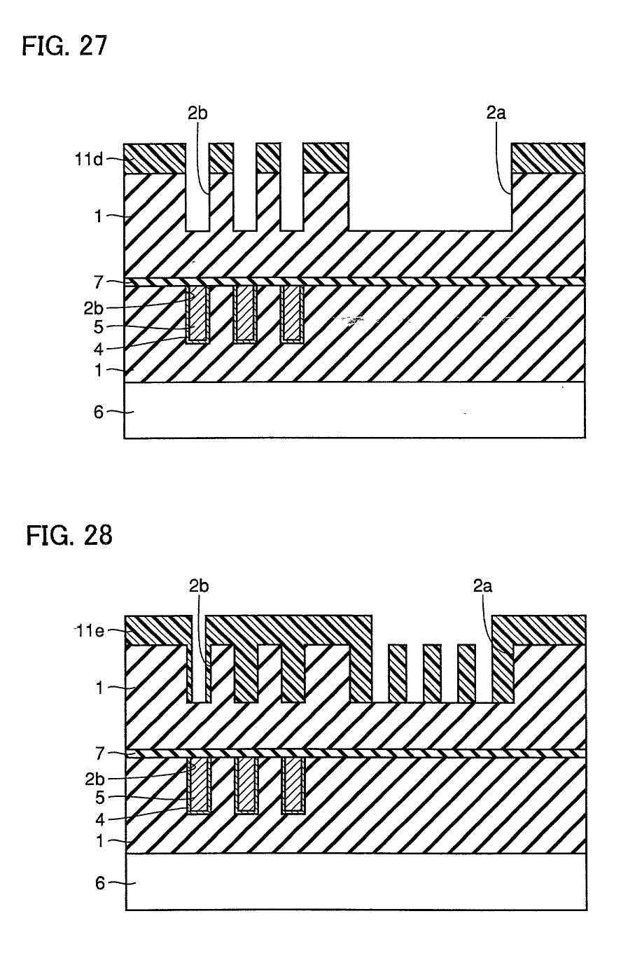

First, referring to FIG. 27, an insulating film 1 is formed on a semiconductor substrate or a lower insulating film 6. Interconnection grooves 2b are formed on this insulating film 1, and lower-layer wires, constituted by a barrier metal 4 and a conductive layer 5, are formed so as to be embedded in the interconnection grooves 2b.

On these lower-layer wires 4, 5 is formed an SiN film having a thickness of, for example, 100 nm, by a plasma CVD method as an etching stopper layer 7. On this etching stopper layer 7 is formed an SiO₂ film having a thickness of, for example, 1.3 μm, by a plasma CVD method as an insulating film 1. These etching stopper layer 7 and insulating film 1 are formed as interlayer insulating films.

A resist pattern 11d having a interconnection pattern formed therein is formed on the insulating film 1 by a photolithographic technique. The insulating film 1 is subjected to a reactive ion etching process with a depth of 0.7 μm using this resist pattern 11d as a mask so that interconnection grooves 2a, 2b are formed. Thereafter, the resist pattern 11d is removed, for example, ashing.

Referring to FIG. 28, a resist pattern 11e having a pattern of connection holes formed therein is formed on the insulating film 1 by a photolithographic technique. In this photolithographic process, together with the pattern of the connection holes, a groove pattern is simultaneously transferred on the resist pattern 11e along the length direction of the interconnection. This groove pattern is a pattern of groove-shaped unevenness to be formed on the bottom portion of each of the interconnection grooves having a width of not less than 5 μm, and the unevenness have a width of 0.4 82 m and a space of 0.6 μm. The insulating film 1 is subjected to a reactive ion etching process by using the resist pattern 11e as a mask.

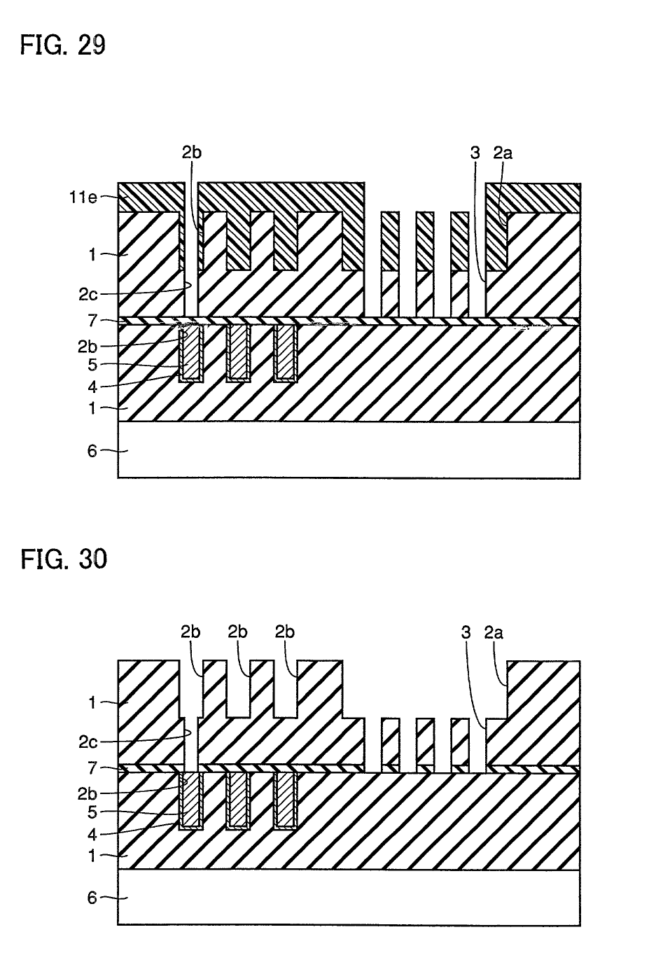

Referring to FIG. 29, through this etching process, connection holes 2c and grooves 3 for unevenness, which reaches the surface of the etching stopper layer 7, are formed. Thereafter, the resist pattern 11e is removed by, for example, ashing.

Referring to FIG. 30, in order to remove the etching stopper layer 7 exposed from the connection holes 2c and the grooves 3 for unevenness, etching is carried out on the entire surface of the SiN film. Thus, the connection holes 2c to the lower wires 4, 5 and the unevenness 3 constituted by a plurality of grooves are formed.

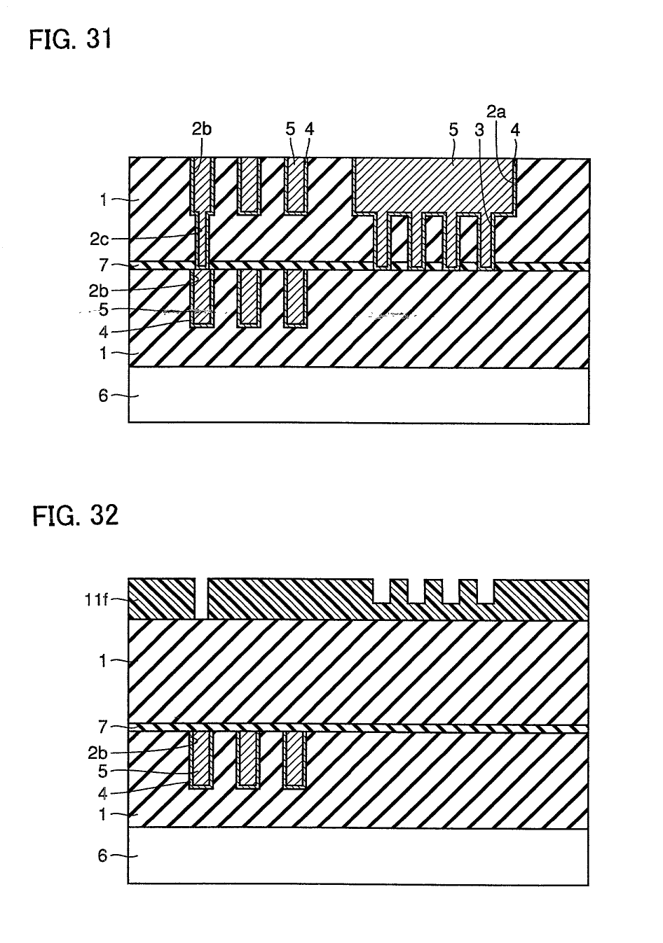

Referring to FIG. 31, for example, a TaN film is formed on the insulating film 1 as barrier metal 4 by sputtering, with a thickness of 20 nm, and, for example, a Cu film is formed thereon as a seed layer for a plating film by sputtering, with a thickness of 150 nm. Then, an electrolytic plating process is carried out in a plating solution of a copper sulfate bath so that the Cu film 5 is formed until it has been embedded in the interconnection grooves 2a, 2b. The current for the electrolytic plating is set to 5A. Moreover, the Cu film 5 and the barrier metal 4 are abraded and removed by the CMP method until at least the upper surface of the insulating film 1 has been exposed so that wires that are embedded in the interconnection grooves 2a, 2b are formed.

As described above, in the same manner as the twelfth embodiment, the resulting effect is that, even in the case of wide wires, a low resistivity is achieved with less deviation in resistance. Moreover, the unevenness 3 located on the bottom portion of each groove 2a having a width of not less than 5 μm can be formed simultaneously with the connection holes 2c; therefore, as compared with the twelfth embodiment, it becomes possible to reduce the number of photolithographic, etching and ashing processes.

Here, in the present embodiment, an explanation has been given of an example in which unevenness 3 constituted by a plurality of grooves are formed as the unevenness 3 on the bottom portion of the groove 2a; however, as described in the second embodiment, the unevenness 3 constituted by a plurality of holes may be formed, or as described in the sixth, seventh and tenth embodiments, the unevenness constituted by a plurality of tapered grooves or holes may be formed, and in any of these cases, it becomes possible to obtain the same effects as those of the present embodiment.

Moreover, the etching stopper layer 7 is placed only on the lower-layer wires 4, 5; however, the insulating film 1 may be divided into upper and lower two layers, and an etching stopper layer against etching to the grooves may be interpolated between these two layers.

(Sixteenth Embodiment)

First, referring to FIG. 32, an insulating film 1 is formed on a semiconductor substrate or a lower insulating film 6. Interconnection grooves 2b are formed on this insulating film 1, and lower-layer wires, constituted by a barrier metal 4 and a conductive layer 5, are formed so as to be embedded in the interconnection grooves 2b.

On these lower-layer wires 4, 5 is formed an SiN film having a thickness of, for example, 100 nm, by a plasma CVD method as an etching stopper layer 7. On this etching stopper layer 7 is formed an SiO₂ film having a thickness of, for example, 1.3 μm, by a plasma CVD method as an insulating film 1. These etching stopper layer 7 and insulating film 1 are formed as interlayer insulating films.

A resist pattern 11f having a pattern of connection holes formed therein is formed on the insulating film 1 by a photolithographic technique. In this photolithographic process, together with the pattern of the connection holes, a groove pattern is simultaneously transferred on the resist pattern 1 if along the length direction of the interconnection. This groove pattern is a pattern of groove-shaped unevenness to be formed on the bottom portion of each of the interconnection grooves having a width of not less than 5 μm, and the unevenness have a width of 0.2 μm and a space of 0.2 μm. Upon transferring the resist pattern 11f, portions of the transferring mask corresponding to the groove pattern are made to have halftone so as to allow light to partially pass; thus, it is possible to form unevenness on the groove pattern portions of the resist pattern 11f. The insulating film 1 is subjected to a reactive ion etching by using this resist pattern 11f as a mask.

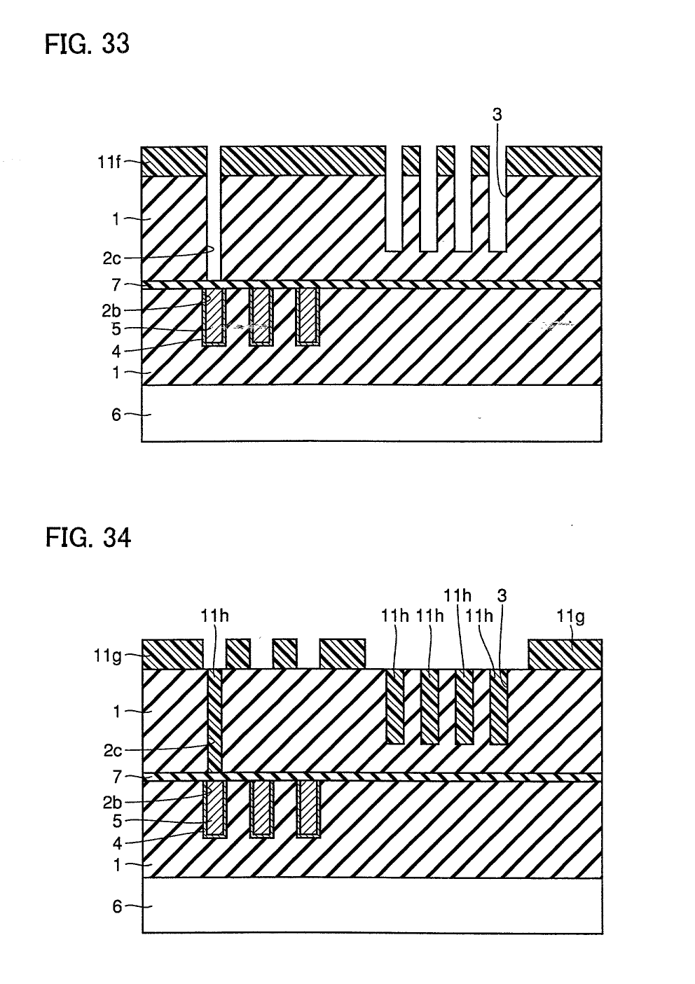

Referring to FIG. 33, this etching process allows the connection holes 2c to reach the surface of the etching stopper layer 7. In contrast, with respect to the groove patterns, the film thickness of the resist pattern 11f decreases as the etching process progresses, with the result that the concave portions of the unevenness penetrate the resist. Thereafter, grooves 3 for unevenness are formed in the insulating film 1 using the resist pattern 11f as a mask. In this manner, the grooves 3 for unevenness are formed simultaneously as the connection holes 2c are formed. Thereafter, the resist pattern 11f is removed by, for example, ashing.

Referring to FIG. 34, SOG 11h is applied onto the insulating film 1 so as to be embedded in the connection holes 2c and the grooves 3 for unevenness. Moreover, a resist pattern 11g having a interconnection pattern formed therein is formed on the insulating film 1 by a photolithographic technique. The insulating film 1 is subjected to a reactive ion etching process by using the resist pattern 11g as a mask.

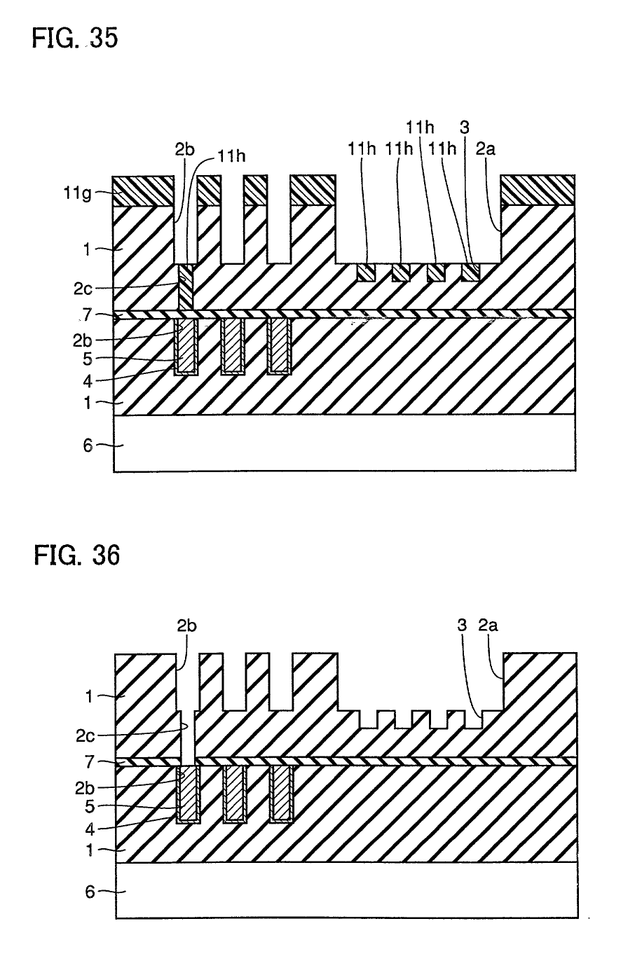

Referring to FIG. 35, the above-mentioned etching process forms interconnection grooves 2a, 2b having a depth of, for example, 0.7 μm on the insulating film 1. Then, the resist pattern 11g is removed by ashing, and the SOG 11h is removed by low-concentration hydrofluoric acid.

Referring to FIG. 36, in order to remove the etching stopper layer 7 exposed from the connection holes 2c, etching is carried out on the entire surface of the SiN film. Thus, the connection holes 2c to the lower wires 4, 5 and the unevenness 3 constituted by a plurality of grooves are formed.

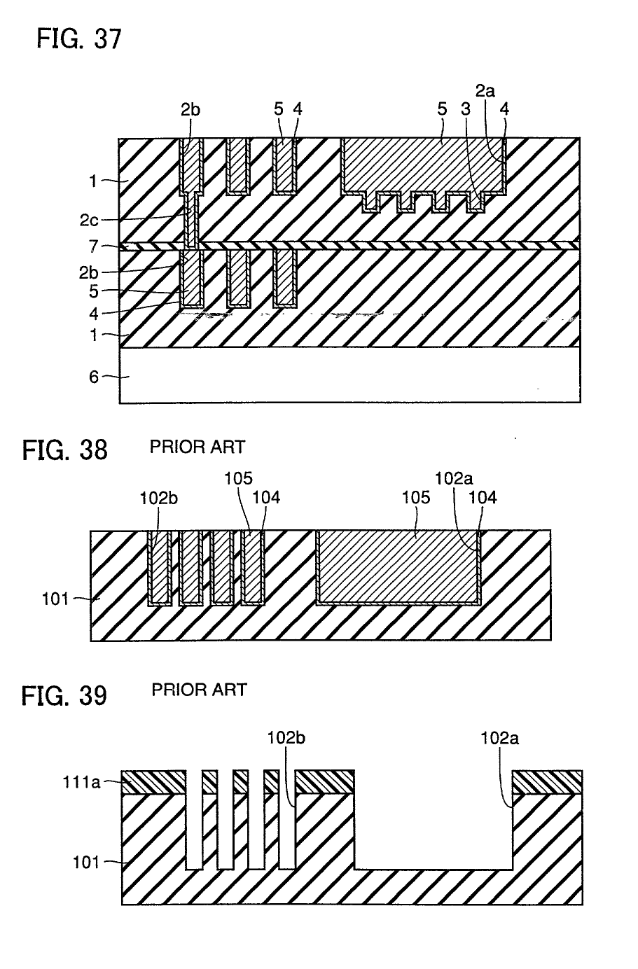

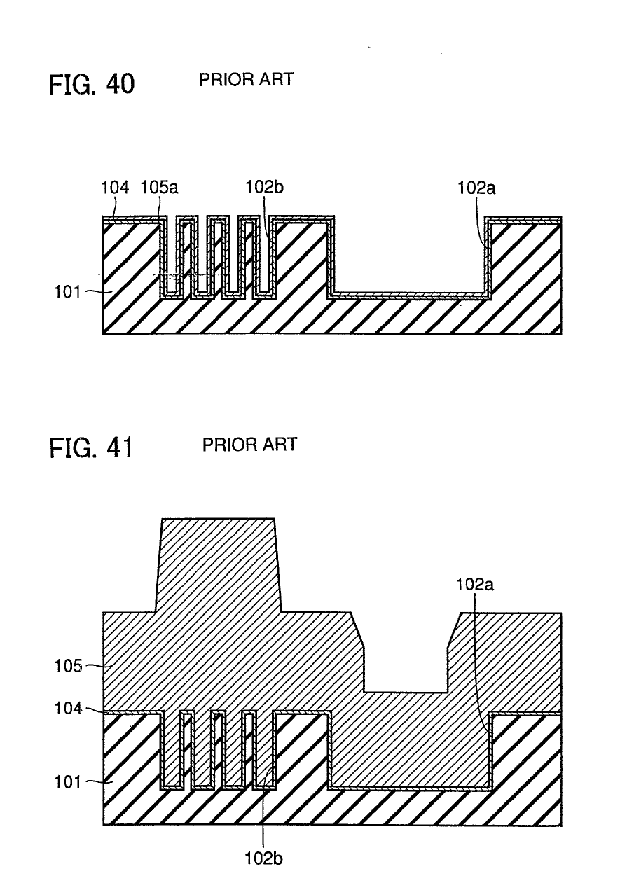

Referring to FIG. 37, for example, a TaN film is formed on the insulating film 1 as barrier metal 4 by sputtering, with a thickness of 20 nm, and, for example, a Cu film is formed thereon as a seed layer for a plating film by sputtering, with a thickness of 150 nm. Then, an electrolytic plating process is carried out in a plating solution of a copper sulfate bath so that the Cu film 5 is formed until it has been embedded in the interconnection grooves 2a, 2b. The current for the electrolytic plating is set to, for example, 5A. Moreover, the Cu film 5 and the barrier metal 4 are abraded and removed by the CMP method until at least the upper surface of the insulating film 1 has been exposed so that wires that are embedded in the interconnection grooves 2a, 2b are formed.

As described above, in the same manner as the twelfth embodiment, the resulting effect is that, even in the case of wide wires, a low resistivity is achieved with less deviation in resistance. Moreover, the unevenness 3 located on the bottom portion of each interconnection groove 2a having a width of not less than 5 μm can be formed simultaneously with the connection holes 2c; therefore, as compared with the twelfth embodiment, it becomes possible to reduce the number of photolithographic, etching and ashing processes.

Moreover, in the above-mentioned thirteenth, fourteenth and fifteenth embodiments, the concave and convex portions are formed in the same manner as the connection holes, with the result that the unevenness are allowed to reach the interlayer insulating film placed as the lower layer. For this reason, the disadvantage of this structure is that no lower interconnection is formed below the wide wire having the unevenness formed on its bottom portion; however, in the present embodiment, since the unevenness are not allowed to reach the interlayer insulating film placed as the lower layer so that it is possible to avoid the above-mentioned disadvantage.

Additionally, in the present embodiment, the pattern of the unevenness is formed finely to such an extent that the pattern of the concave and convex is not resolved so that the resist of the exposing portions is allowed to remain slightly; however, the exposure to the unevenness may be reduced. The exposure can be properly adjusted by using a halftone mask, etc., or controlling the exposure using an electron beam at the time of exposure.

Here, in the present embodiment, an explanation has been given of an example in which unevenness 3 constituted by a plurality of grooves are formed as the unevenness 3 on the bottom portion of the groove 2a; however, as described in the second embodiment, the unevenness 3 constituted by a plurality of holes may be formed, or as described in the sixth, seventh, and tenth embodiments, the unevenness constituted by a plurality of tapered grooves or holes may be formed, and in any of these cases, it becomes possible to obtain the same effects as those of the present embodiment.

Moreover, in the present embodiment, with respect to a material to be injected into the connection holes 2c and the grooves for unevenness 3, the SOG is used in the present embodiment; however, besides the SOG, other organic materials, such as organic SOG and resist, may be used.

Moreover, the etching stopper layer 7 is placed only on the lower-layer wires 4, 5; however, the insulating film 1 may be divided into upper and lower two layers, and an etching stopper layer against etching to the grooves may be interpolated between these two layers.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device comprising:
an insulating layer having a surface in which a plurality of grooves having different widths are formed; and
a conductive layer formed by filling the inside of each of said grooves with at least plating,
wherein unevenness is formed on a bottom portion of each of some grooves among said plurality of grooves.

2. The semiconductor device according to claim 1, wherein said unevenness is formed on a bottom portion of a groove that has a ratio of the depth to the width of not more than 0.7.

3. The semiconductor device according to claim 1, wherein said unevenness is formed on a bottom portion of a groove that has a ratio of the depth to the width of not more than 0.35.

4. The semiconductor device according to claim 1, wherein the concave portion of said unevenness has a groove shape, and said concave portion has a ratio of the depth to the width of greater than 0.35.

5. The semiconductor device according to claim 1, wherein the concave portion of said unevenness has a groove shape, and said concave portion has a ratio of the depth to the width of greater than 0.7.

6. The semiconductor device according to claim 1, wherein the concave portion of said unevenness has a hole shape, and said concave portion has a ratio of the depth to the aperture diameter of greater than 0.35.

7. The semiconductor device according to claim 1, wherein the concave portion of said unevenness has a hole shape, and said concave

8. The semiconductor device according to claim 1, wherein the concave portion of said unevenness has slanting side faces with the two side faces crossing each other in its cross-section.

9. The semiconductor device according to claim 8, wherein the side face of said concave portion is slanted with an angle greater than 20 degrees against an upper surface of said insulating layer.

10. The semiconductor device according to claim 1, wherein the pitch of said concave portions of said unevenness is set to be not more than 4 times the width or the aperture diameter of the concave portion.

11. A manufacturing method of a semiconductor device comprising: the steps of:
forming a plurality of grooves having different widths on a surface of an insulating layer, and forming unevenness on a bottom surface of each of some grooves among said plurality of grooves;
depositing a metal film on said insulating layer by plating so as to be embedded in said plurality of grooves and said unevenness; and
removing said metal film by chemical mechanical polishing until at least the upper surface of said insulating layer is exposed so that said metal film is allowed to remain in said grooves and said unevenness to form a interconnection layer.

12. The manufacturing method of a semiconductor device according to claim 11, further comprising the steps of:
forming a lower interconnection layer as a lower layer beneath said insulating layer; and
forming a connection hole for connecting said lower interconnection layer and said interconnection layer in said insulating layer,
wherein, prior to the formation of said grooves, said connection hole and said unevenness are simultaneously formed.
